(19) United States
(12) Patent Application Publication
(10) Pub. No.: US 2026/0312186 A1
(43) Pub. Date: Oct. 8, 2026

(54) BATTERY PROTECTION SYSTEMS

(71) Applicants: CPS Technology Holdings LLC, New York, NY (US); Clarios Advanced Solutions GmbH, Hannover (DE); Clarios Germany GmbH & Co. KG, Hannover (DE)

(72) Inventors: Nicholas E. ELISON, Mequon, WI (US); Joerg BIRKHOLZ, Sarstedt (DE); Martin WIEGMANN, Borstel (DE); Marco JANSEN, Celle/Groß Hehlen (DE); Ethan Michael CORR, Milwaukee, WI (US); Jeffrey Michael WATTS, Milwaukee, WI (US); Julius Martin SCHWAB, Hannover (DE)

(21) Appl. No.: 19/490,274

(22) PCT Filed: Jun. 6, 2024
(86) PCT No.: PCT/US2024/032787

§ 371 Date: Dec. 4, 2025

Related U.S. Application Data
(60) Provisional application No. 63/506,681, filed on Jun. 7, 2023.

(51) Int. Cl. H01M 10/663; B60H 1/00; B60L 58/12; B60L 58/26; B60L 58/27; G01R 31/3842; G01R 31/389; G01R 31/396; H01G 11/18; H01M 10/42; H01M 10/48; H01M 10/613; H01M 10/615; H01M 10/625; H01M 10/6563

(52) U.S. Cl. CPC H01M 10/663; B60H 1/00278; B60H 1/00485; B60H 1/00792; B60L 58/12; B60L 58/26; B60L 58/27; G01R 31/3842; G01R 31/389; G01R 31/396; H01M 10/425; H01M 10/486; H01M 10/613; H01M 10/615; H01M 10/625; H01M 10/6563; B60L 2240/545; H01G 11/18; H01M 2010/4271; H01M 2220/20

(57) ABSTRACT

A thermal management system associated with a vehicle and at least one battery with an air conditioning (AC) system having a first AC line and a first communication link. The thermal management system includes a fan in fluid communication with the at least one battery and a sensor to measure a temperature of the of the at least one battery. The thermal management system includes a battery management system (BMS) in communication with the sensor and the fan, the BMS configurable to communicate with the AC system. The BMS determines, via the sensor, the temperature of the at least one battery and performs thermal management of the at least one battery at least by causing the AC system and the fan to one or both of cool and heat the at least one battery based on the determined temperature.

### TECHNICAL FIELD

This disclosure relates to batteries, and in particular to a method and system for thermal management and protecting an energy storage module (e.g., battery).

### INTRODUCTION

Motor-powered and/or electrically powered vehicles tend to rely on using one or more battery systems for providing a starting power (e.g., power used to crank and start an engine) and/or at least a portion of a motion power for the vehicle. Such vehicles may include one or more of an air-or watercraft, a rail-guided vehicle, a street vehicle, etc., where a street vehicle may refer to, for example, cars, trucks, buses, recreational vehicles, etc. Also, an air vehicle may refer to, for example, airplanes, helicopters, rockets, blimps, etc. A watercraft vehicle may refer to, for example, boats, ships, hovercrafts, submarines, etc. A rail guided vehicle may refer to, for example, railcars, railbuses, freight cars, trains, locomotives, etc.

Any temperature change may impact the battery in some way. In some cases, batteries are exposed to temperature (e.g., above a particular threshold) which may cause the battery to malfunction. In other cases, batteries are exposed to temperature (e.g., below another threshold) which may also cause the battery to malfunction. For example, the battery of a vehicle may be exposed to heat from the vehicle engine. When the battery is exposed to heat over a period of time, the temperature of the battery components may rise, which may lead to undesirable performance, failure, etc. Hotter temperatures tend to increase power availability within the battery but may also increase corrosion/decay.

Also, the battery of a vehicle may be exposed to cold from the outside. When the battery is exposed to cold temperatures over a period of time, this may cause the battery's internal resistance to increase, which in turn may make it more challenging for the battery to supply the necessary power to turn over the engine. Colder temperatures tend to reduce power availability within the battery but may also slow corrosion/decay.

Further, the heat, cool and/or other factors may cause the pressure inside the battery to increase and/or the battery to swell. In addition, a battery such as a vehicle battery may be exposed to crushing forces or internal forces such as exerted to the battery when the vehicle crashes or the cells within the battery swell.

### SUMMARY

Some embodiments advantageously provide a method, apparatus, and system for providing battery protection. In some embodiments, the battery provides a gas venting arrangement and/or battery cooling arrangement. In some other embodiments, vent gas from the battery and cooling air are separated. In an embodiment, crush and cell swelling protection is provided. In another embodiments, guide welding (e.g., infra-red (IR) guide welding (i.e., coupling) of a battery cover and/or battery housing and/or cell housing (e.g., plastic cell swelling resistor/restrictor (CSR) is provided.

According to one aspect, a thermal management system associated with a vehicle and at least one battery is described. The vehicle has an air conditioning (AC) system with a first AC line and a first communication link. The AC system is in fluid communication with the battery through the first AC line and in electrical communication with the battery through the first communication link. The thermal management system has a fan that is in fluid communication with the at least one battery and a sensor configured to measure a temperature of the of the at least one battery. The thermal management system also has a battery management system (BMS) in communication with the sensor and the fan. The BMS is configurable to be in communication with the AC system. Also, the BMS is configured to determine, via the sensor, the temperature of the at least one battery and perform thermal management of the at least one battery at least by causing the AC system and the fan to one or both of cool and heat the at least one battery based on the determined temperature.

In some embodiments, the sensor is further configured to measure at least one battery parameter. Also, the BMS is further configured to determine, via the sensor, a battery parameter of the at least one battery. Performing thermal management of the at least one battery is at least by causing the AC system and the fan to one or both of cool and heat battery is based on the determined temperature and the at least one battery parameter.

In some other embodiments, the at least one battery parameter includes at least one of a battery resistance, a battery cell voltage, a state of charge of the battery, a battery current, a time parameter, and a frequency parameter.

In some embodiments, the sensor is further configured to measure a battery resistance. Also, the BMS is further configured to determine, via the sensor, a battery resistance parameter of the at least one battery. Performing thermal management of the at least one battery is at least by causing the AC system and the fan to one or both of cool and heat battery is based on the determined temperature and the determined battery resistance.

In some other embodiments, the sensor is further configured to measure a battery cell voltage. Also, the BMS is further configured to determine, via the sensor, a battery cell voltage parameter of the at least one battery. Performing thermal management of the at least one battery is at least by causing the AC system and the fan to one or both of cool and heat battery is based on the determined temperature and the determined battery cell voltage of the at least one battery.

In some embodiments, the sensor is further configured to measure a state of charge of the at least one battery. Also, the BMS is further configured to determine, via the sensor, a state of charge parameter of the at least one battery. Performing thermal management of the at least one battery is at least by causing the AC system and the fan to one or both of cool and heat battery is based on the determined temperature and the determined state of charge of the at least one battery.

In some other embodiments, the sensor is further configured to measure a battery current of the at least one battery. Also, the BMS is further configured to determine, via the sensor, a battery current parameter of the at least one battery. Performing thermal management of the at least one battery is at least by causing the AC system and the fan to one or both of cool and heat battery is based on the determined temperature and the determined battery current of the at least one battery.

In some embodiments, the battery is at least one of a lead acid battery, a lithium ion battery, a nickel-metal hydride battery, and an ultracapacitor.

In some other embodiments, the AC system receives signals from the BMS to activate the AC system or deactivate the AC system.

In some embodiments, the AC system is activated when the BMS determines that cooling or heating is needed based upon the determined temperature and the determined battery parameter.

In some other embodiments, the fan receives signals from the BMS to increase the fan blower speed, decrease the fan blower speed, or deactivate the fan.

In some embodiments, the fan blower speed is increased when the BMS determines that cooling or heating is needed based upon the determined temperature and the determined battery parameter.

In some other embodiments, the first AC line further comprises at least one valve in the first AC line, the first AC line being in fluid communication with the AC system and the battery. When the BMS determines that cooling or heating is needed based upon the determined temperature and the determined battery parameter, the BMS causes the at least one valve to change a valve position to an open position so that cooling or warming air can flow from the AC system to the battery.

In some embodiments, when the BMS determines that no cooling or heating is needed based upon the determined temperature and the determined battery parameter, the BMS causes the at least one valve to change the valve position from the open position to a closed position so that cooling or warming air cannot flow from the AC system to the battery.

In some other embodiments, the vehicle further includes a second communication link in communication with the BMS, a device, and the vehicle. The vehicle also has a second AC line) in fluid in communication with the AC system and the vehicle. The first AC line is in communication with the battery and the second AC line is in communication with the vehicle and the AC system. The first AC line further includes a valve that is movable from an open position to a closed position, Also, moving the valve into the closed position in the first AC line will prevent solids, liquids, and gasses from flowing past the valve in the first AC line. Moving the valve into the open position will allow solids, liquids, and gasses to flow past the valve in the first AC line. When the device determines that cooling or heating is needed based upon a determined temperature in the vehicle, the AC system is activated and cooling or heating air is sent into the second AC line into the vehicle.

According to another aspect, a system for a vehicle having an air conditioning (AC) system with a first AC line, a second AC line, a first communication link, and a second communication link is described. The AC system is in fluid communication with the vehicle through a second air conditioning line and in electrical communication with the vehicle. The system has a thermal management system and the thermal management system includes a battery that is in communication with the vehicle, in fluid communication with the AC system through the first AC line, and in electrical communication with the AC system through the first communication link. Also, the thermal management system has as fan that is proximate the battery and in fluid communication with the battery and a BMS having a first sensor that is configured to measure a first temperature of the battery and a second sensor configured to measure a second temperature of the vehicle. The BMS is in communication with the AC system and the fan and a device is in communication with the BMS, the first sensor and the second sensor. The device determines, via the first sensor, a first temperature parameter of the battery based on the first temperature. Also, the device determines, via the second sensor, a second temperature parameter of the vehicle based on the second temperature. The device also performs thermal management of the battery at least by causing the AC system and the fan to one or both of cool and heat battery based on one or both of the first temperature parameter and the second temperature parameter.

In some embodiments, the BMS can measure at least one battery parameter.

In some other embodiments, the at least one battery parameter includes at least one of a battery resistance, a battery cell voltage, a battery current, a battery state of charge, a time parameter, a frequency parameter, and a temperature parameter.

According to another aspect, a method for thermally managing a battery is described. The method is implemented by a thermal management system associated with at least one battery and has a fan that is proximate the battery and in fluid communication with the battery, a sensor configured to measure a temperature of the of the at least one battery, and a BMS in communication with the sensor and the fan. The thermal managing system is associated with a vehicle having an air conditioning (AC) system in fluid communication with the battery. The method includes determining, via the sensor and the BMS, a temperature parameter of the at least one battery. The method also includes performing, via the BMS, thermal management of the at least one battery at least by causing the AC system and the fan to one or both of cool and heat battery based on the determined temperature.

In some embodiments, the method further comprises continuously monitoring the temperature of the battery using the sensor.

### BRIEF DESCRIPTION OF THE DRAWINGS

A more complete understanding of embodiments described herein, and the attendant advantages and features thereof, will be more readily understood by reference to the following detailed description when considered in conjunction with the accompanying drawings wherein:

FIG. 1 is a diagram of an example system according to principles disclosed herein;

FIG. 2 shows an example battery constructed in accordance with the principles of the present disclosure;

FIG. 3 is a block diagram of some entities in the system according to some embodiments of the present disclosure;

FIG. 4 shows an example system according to some embodiments of the present disclosure;

FIG. 5 shows another example system according to some embodiments of the present disclosure;

FIG. 6A shows a perspective view of an example battery according to some embodiments of the present disclosure;

FIG. 6B shows an exploded view of the example battery of FIG. 6A according to some embodiments of the present disclosure;

FIG. 7 shows a perspective view of an example battery according to some embodiments of the present disclosure;

FIG. 8 shows another perspective view of an example battery according to some embodiments of the present disclosure;

FIG. 9 shows a side view of an example battery according to some embodiments of the present disclosure;

FIG. 10 shows an example battery housing according to some embodiments of the present disclosure;

FIG. 11 shows an example battery housing, cell housing, and cells according to some embodiments of the present disclosure;

FIG. 12 shows an example battery housing, cell housing, cells, and bust bar according to some embodiments of the present disclosure;

FIG. 13 shows a cross section view of an example battery including battery cells according to some embodiments of the present disclosure;

FIG. 14 shows another cross section view of an example battery according to some embodiments of the present disclosure;

FIG. 15 shows an example battery and tray according to some embodiments of the present disclosure;

FIG. 16 shows a section of an example battery and tray according to some embodiments of the present disclosure;

FIG. 17 shows an example cell housing box according to some embodiments of the present disclosure;

FIG. 18 shows an exploded view of an example battery housing and isolation layers according to some embodiments of the present disclosure;

FIG. 19 shows another example cover and components according to some embodiments of the present disclosure;

FIG. 20 shows an example battery housing according to some embodiments of the present disclosure;

FIG. 21 shows a perspective view of an example cell housing according to some embodiments of the present disclosure;

FIG. 22 shows a side view of an example cell housing according to some embodiments of the present disclosure;

FIG. 23 shows an example method associated with a battery protection system according to some embodiments of the present disclosure; and

FIG. 24 shows an example method associated with thermally managing a battery according to some embodiments of the present disclosure.

### DETAILED DESCRIPTION

Before describing in detail exemplary embodiments, it is noted that the embodiments reside primarily in combinations of apparatus components and processing steps related to protection of batteries. Accordingly, the system and method components have been represented where appropriate by conventional symbols in the drawings, showing only those specific details that are pertinent to understanding the embodiments of the present disclosure so as not to obscure the disclosure with details that will be readily apparent to those of ordinary skill in the art having the benefit of the description herein.

As used herein, relational terms, such as “first” and “second,” “top” and “bottom,” and the like, may be used solely to distinguish one entity or element from another entity or element without necessarily requiring or implying any physical or logical relationship or order between such entities or elements. The terminology used herein is for the purpose of describing particular embodiments only and is not intended to be limiting of the concepts described herein. As used herein, the singular forms “a”, “an” and “the” are intended to include the plural forms as well, unless the context clearly indicates otherwise. It will be further understood that the terms “comprises,” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

In some embodiments, the term “parameter” refers to any parameter related to a battery (and/or its components), battery performance, battery management, operation, vehicle parameters, device systems parameters, etc., as well as performance, management, operation, etc., of the device in which the battery is installed. In some embodiments the parameter may be an electrical parameter such as power, voltage, current, state of charge (SoC), resistance (e.g., battery resistance), voltage (e.g., cell voltage, open circuit voltage (OCV)) and/or any other parameter such as temperature, pressure, frequency parameter (e.g., frequency of a pulse, frequency at which an operation mode is on and/or off and/or activated and/or deactivated), etc. A frequency parameter may refer to a time parameter such as the time a pulse is on or off, the time an operation mode is on/off and/or activated/deactivated. A parameter threshold may refer to a threshold associated with a parameter.

A battery health condition may refer to any condition associated with a battery (and/or devices, systems, components associated with the battery such as health of the battery and/or of a vehicle/vehicle system). A battery health condition may include a parameter (e.g., temperature, pressure) associated with the battery and/or its components that is greater than or equal to a predetermined parameter threshold. A battery health condition may also include deformation as a result of crushing force and/or a failure (e.g., a catastrophic failure of a battery/system, a potential failure, a condition associated with a potential failure, triggered system failures, battery pack failure, fail to start/operate vehicle, etc.), a degradation condition (e.g., inability to meet a user/functional/ specification requirement such as when a parameter is under/over a predetermined threshold), an internal short circuit, an internal resistance value being under a predetermined threshold (e.g. indicating a short circuit condition), etc.

An operation mode (e.g., power consumption mode) may refer to one or more modes of operating a battery and/or battery management system (BMS) and/or associated vehicle and/or associated system and/or associated device. The operation mode may be based on one parameter such state of charge of the battery. Further, the operation mode may comprise normal mode, sleep mode, shutdown mode, doze mode, low power consumption mode, etc.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

In embodiments described herein, the joining term, “in communication with” and the like, may be used to indicate electrical or data communication, which may be accomplished by physical contact, induction, electromagnetic radiation, radio signaling, infrared signaling or optical signaling, for example. Further, “in communication with” may be used to indicate in fluid communication with such as when an air inlet coupled to a line (e.g., cold air line) of an air conditioning system and the air inlet receives air from the line. One having ordinary skill in the art will appreciate that multiple components may interoperate, and modifications and variations are possible of achieving the electrical and data, and mechanical communication.

In some embodiments, the general description elements in the form of “one of A and B” corresponds to A or B. In some embodiments, at least one of A and B corresponds to A, B or AB, or to one or more of A and B. In some embodiments, at least one of A, B and C corresponds to one or more of A, B and C, and/or A, B, C or a combination thereof.

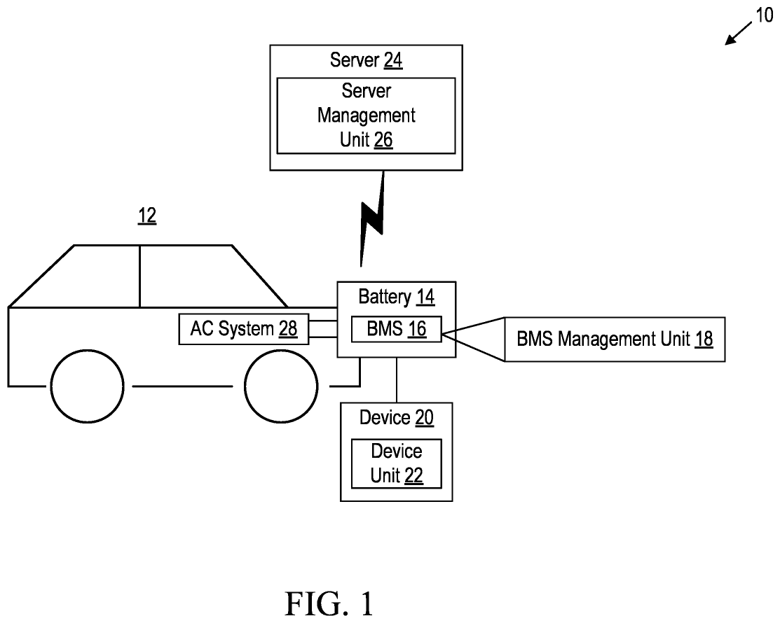

Referring now to the drawing figures, in which like elements are referred to by like reference numerals, there is shown in FIG. 1 a diagram of a system 10, according to an embodiment, which comprises one or more vehicles 12, e.g., a car, motorcycle, scooter, golf cart, light utility vehicle, etc. The vehicle 12 comprises battery 14 for powering at least one function of vehicle 12. In some embodiments, battery 14 may be a lead-acid battery that includes one or more energy storage modules/cells. Although a lead-acid battery is described herein, the teachings described herein are equally applicable to other battery types including but not limited to lithium-ion batteries, nickel-metal hydride batteries, and ultracapacitors. Battery 14 may include one or more batteries such as a first battery 14a, second battery 14b, third battery 14c, fourth battery 14d, etc., e.g., electrically connected (e.g., in parallel, series, etc.) as part of a battery pack. Although battery 14 is shown in conjunction with a vehicle 12, battery 14 is not limited as such and may be used in conjunction with any other component (e.g., such as to power any other system component).

Battery 14 includes battery management system (BMS) 16 that is configured to perform one or more battery management functions described herein. In some embodiments, the BMS 16 may measure/determine certain battery parameters, e.g., resistance (e.g., battery resistance), voltage (e.g., cell voltage), current, state of charge (SoC), a time parameter, a frequency parameter, a temperature parameter, etc., and transmit/receive data (and/or signals such as control signals) to/from another system/device. A BMS 16 is configured to include a BMS management unit 18 that may be configured to perform one or more functions as described herein such as determining one or more parameters, steps, and/or processes associated with battery diagnostics.

System 10 may further include device 20 comprising device unit 22 that may be configured to perform one or more functions as described herein such as provide one or more device functions, e.g., a device configurable to monitor and/or control and/or diagnose vehicle 12 (and/or any of its components such an air conditioning system) and/or battery 14 and/or BMS 16, etc. Accordingly, the device unit 22 and device 20 may monitor and/or control, and/or diagnose the air conditioning system within the vehicle 12. Device 20 may be physically and/or electrically connected to one or more components of system 10 such as vehicle 12 and/or battery 14 and/or BMS 16, e.g., to display an indication of parameter. Device 20 may be configured to perform any of the functions of the BMS 16 as described herein. System 10 may also include server 24 comprising server management unit 26, which may be configured to perform one or more functions as described herein such as determining a battery parameter, battery life, a battery health condition and/or operation mode of battery 14, schedule a maintenance action based on the determined battery health condition and/or operation mode, etc.

Vehicle 12 may include an air conditioning (AC) system 28 which may be coupled to battery 14. It will be understood that AC system 28 may refer to any thermal regulating system including a heating, cooling, and/or any other thermal regulating system. For example, AC system 28 may be in fluid communication with battery 14 (e.g., an air inlet of battery 14) such as to provide battery 14 with air (e.g., cooling air, hot air, etc.). Further, AC system 28 may be in fluid communication with battery 14 (e.g., BMS 16) such as to transmit and/or receive signals (for monitoring and/or controlling battery 14, AC system 28, and/or any other components of system 10). Thus, AC system 28 may provide thermal control such as control of a temperature of battery 14 (e.g., providing cooling air, heating, etc.). Although AC system 28 is described as being comprised in a vehicle 12, the embodiments of the present disclosure are not limited as such, and the AC system 28 may be part of another component or standalone as well. In some embodiments, AC system 28 is comprised in vehicle 12 and arranged to provide thermal regulation such as heating, cooling, ventilation to the cabin of vehicle 12. AC system 28 may be arranged with controls for setting temperature settings, blower speed, AC modes, etc.

It is contemplated that one or more entities of system 10 are in communication with each other via one or more of wireless communication, power communication, wired communication, fluid communication, etc. For example, vehicle 12, battery 14, device 20, and server 24 may communicate with each other directly or indirectly using wireless communication, power communication, wired communication, etc. Further, while it may be assumed in one or more embodiments that there is not data or signal communication between battery 14 and vehicle 12, the embodiments described herein are equally applicable to vehicles 12 where there are at least some data/signal communications between battery 14 and vehicle 12. Further, although battery 14 is shown as part of vehicle 12 may be a standalone battery, removably couplable to any component of system 10 such as vehicle 12, etc.

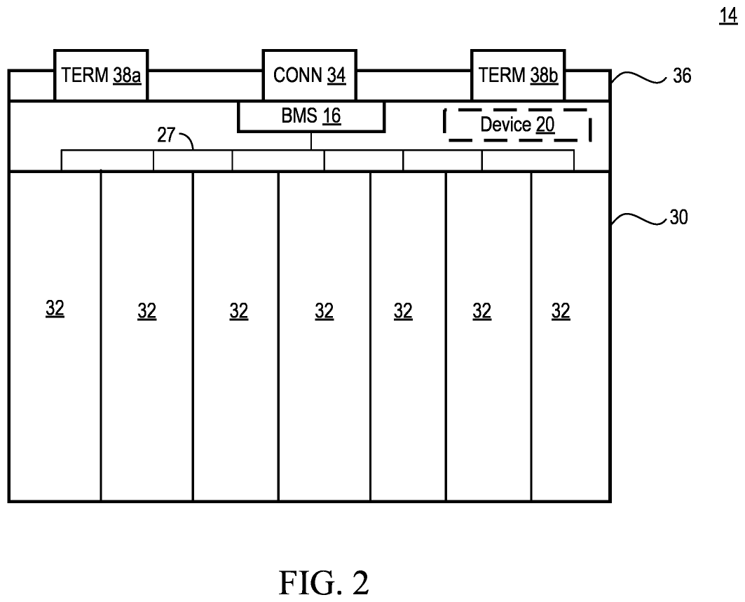

FIG. 2 shows an example battery 14 constructed in accordance with the principles of the present disclosure. Battery 14 includes a housing 30 into which one or more battery components may be positioned. The components may be electrically interconnected (not shown in the FIGS), such as via an electrically conductive bus bar system which electrically interconnects the components in an electrically serial, electrically parallel or combination of electrically serial and parallel manner, depending on the intended voltage and current requirements.

A battery monitoring system (BMS) 16 may be included in the battery 14. BMS 16 may include a monitoring connector 34 that allows for a removable external connection any other component of system 10 (e.g., to the vehicle's data bus, to some other communication device, device 20, etc.) and/or internal connection, e.g., any components of battery 14 and/or BMS 16 and/or device 20. Connector 34 may be comprised in BMS 16 and/or device 20. In some embodiments, connector 34 may be configured to removably couple and/or connect (electrically, physically) to another connector. The monitoring connector 34 can, in some embodiments, be integrated with the housing 30, such as in a cover 36 of the housing 30. Battery 14 also includes terminals, such as a positive terminal 38a and a negative terminal 38b (collectively referred to as terminals 38) to provide the contact points for electrical connection of the battery 14 (e.g., to device 20 such as to power device 20, to the vehicle 12 such as to provide power to the vehicle and/or BMS 16 such as to power BMS 16). Terminals 38 may be arranged to protrude through housing 30, such as protruding through cover 36. Terminals 38 may be electrically connected to the bus bars inside housing 30 and/or directly connected to cells 32 (bus bars and direct connection not shown).

Further, battery 14 may be arranged to provide many power capacities and physical sizes, and to operate under various parameters and parameter ranges. It is also noted that implementations of battery 14 some can be scaled to provide various capacities. For example, in some embodiments, the power capacity of battery 14 can range from 25 Ah to 75 Ah. It is noted, however, that this range is merely an example, and that it is contemplated that embodiments of battery 14 can be arranged to provide less than a 25 Ah capacity or more than a 75 Ah capacity. Power capacity scaling can be accomplished, for example, by using higher or lower power capacity cells 32 in the housing 30, and/or by using fewer or more cells 32 in the housing 30. In some embodiments, battery 14 may be incorporated as part of a vehicle where battery power is needed. Other electrical parameters of the battery 14 can be adjusted/accommodated by using cells 32 that may cumulatively have the desired operational characteristics, e.g., current, voltage, charge, charging capacity/rate, discharge rate, etc. Thermal properties can be managed based on cell 32 characteristics, the use of heat sinks and/or thermal energy discharge plates, etc., within or external to the housing 30. Further, BMS 16 and/or device 20 may be connected to at least one of the cells such as to determine/measure at least one parameter of battery 14 and/or cells 32.

Further, battery 14 may include a plurality of leads 27 (e.g., lead assembly, lead frame), where each lead is electrically connected to a cell 32 and BMS 16. BMS 16 may be configured to determine one or more parameters of each cell 32 via leads 27 such as cell temperature, cell pressure, etc.

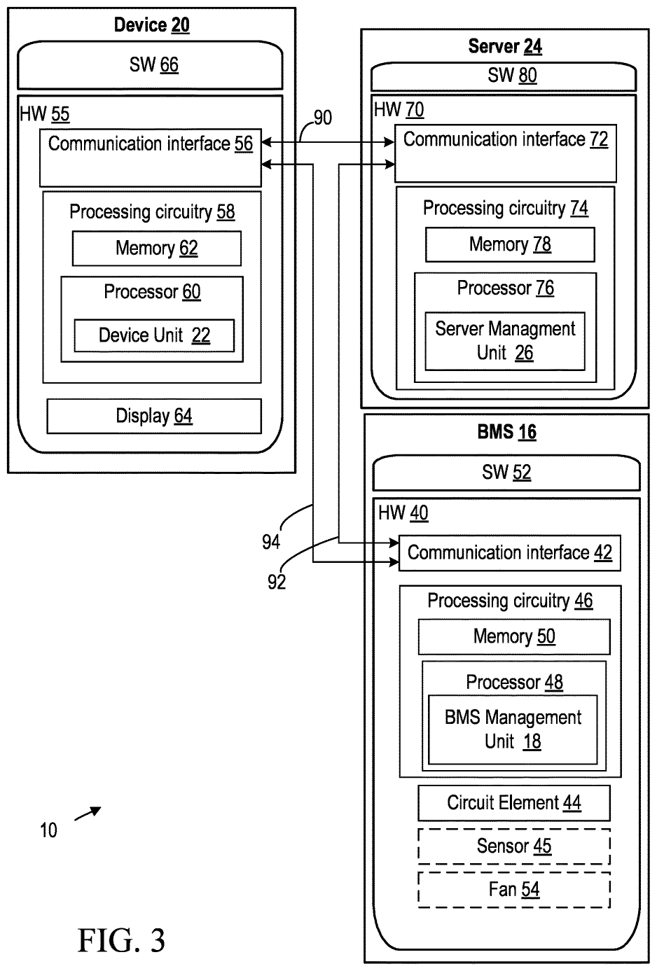

Example implementations, in accordance with an embodiment, of BMS 16, device 20, and server 24 discussed in the preceding paragraphs will now be described with reference to FIG. 3. BMS 16 may have hardware 40 that may include a communication interface 42 that is configured to communicate with one or more entities in system 10 via wired and/or wireless communication. The communication may be protocol based communications.

The hardware 40 includes processing circuitry 46. The processing circuitry 46 may include a processor 48 and memory 50. In particular, in addition to or instead of a processor, such as a central processing unit, and memory, the processing circuitry 46 may comprise integrated circuitry for processing and/or control, e.g., one or more processors and/or processor cores and/or FPGAs (Field Programmable Gate Array) and/or ASICs (Application Specific Integrated Circuitry) adapted to execute instructions. The processor 48 may be configured to access (e.g., write to and/or read from) memory 50, which may include any kind of volatile and/or nonvolatile memory, e.g., cache and/or buffer memory and/or RAM (Random Access Memory) and/or ROM (Read-Only Memory) and/or optical memory and/or EPROM (Erasable Programmable Read-Only Memory). Hardware 40 may also have one or more circuit elements 44 such as resistors, capacitors, inductors, diodes, transistors, ground connections, source elements, sink elements, sensors, etc. Circuit elements 44 may be arranged in any configuration or connection such as series, parallel, combinations thereof, etc. The sensors may be configured to measure battery temperature or other parameters. In some embodiments, BMS 16 includes sensor 45 which may be configured to measure and/or sense one or more parameters, such as parameters associated with battery 14. For example, sensor 45 may be a temperature sensor, but is not limited as such. Also, although sensor 45 is shown as comprised in BMS 16, sensor 45 is not limited as such and may be a remote sensor, standalone, or comprised in any other component of system 10.

Thus, the BMS 16 may further comprise software 52, which is stored in, for example, memory 50, or stored in external memory (e.g., database, etc.) accessible by the BMS 16. The software 52 may be executable by the processing circuitry 46.

The processing circuitry 46 may be configured to control any of the methods and/or processes described herein and/or to cause such methods, and/or processes to be performed, e.g., by BMS 16. The processor 48 corresponds to one or more processors 48 for performing BMS 16 functions described herein. The BMS 16 includes memory 50 that is configured to store data, programmatic software code and/or other information described herein. In some embodiments, the software 52 may include instructions that, when executed by the processor 48 and/or processing circuitry 46, causes the processor 48 and/or processing circuitry 46 to perform the processes described herein with respect to BMS 16. For example, the processing circuitry 46 of the BMS 16 may include BMS management unit 18 that is configured to perform any step and/or task and/or process and/or method and/or feature described in the present disclosure, e.g., determining one or more parameters, steps, and/or processes associated with battery 14. While BMS management unit 18 is illustrated as being part of BMS 16, BMS management unit 18 and associated functions described herein may be implemented in a device separate from BMS 16 such as in battery 14 or another device.

In some embodiments, BMS 16 may be configured to electrically connect to fan 54. In some other embodiments, fan 54 is comprised in battery 14 and the battery 14 may provide power to the fan 54. In some embodiments, fan 54 is part of BMS 16 such as comprised in or by being connected to BMS 16. In some other embodiments, fan 54 is in proximity to battery 14 (e.g., the fan is in fluid communication with battery 14 but is not in direct physical contact with battery 14). In other embodiments, the fan 54 may not be included as part of the components of system 10 and/or the fan 54 may be in proximity with different components of the system 10.

Device 20 may have hardware 55 that may include a communication interface 56 that is configured to communicate with one or more entities in system 10 (and/or outside of system 10) via wired and/or wireless communication. The communication may be protocol based communication. Device 20 may also be configured to electrically connect to battery 14, e.g., to power device 20 and/or receive at least one parameter (and/or parameter data) from battery 14 and/or display the at least one parameter. In some embodiments, device 20 is configured as a vehicle management system that monitors and/or controls one or more vehicle functions such cooling/heating. For example, device 20 may be a vehicle management system that is configured to control AC system 28 and/or any other vehicle functions.

The hardware 55 includes processing circuitry 58. The processing circuitry 58 may include a processor 60 and memory 62. In particular, in addition to or instead of a processor, such as a central processing unit, and memory, the processing circuitry 58 may comprise integrated circuitry for processing and/or control, e.g., one or more processors and/or processor cores and/or FPGAs (Field Programmable Gate Array) and/or ASICs (Application Specific Integrated Circuitry) adapted to execute instructions. The processor 60 may be configured to access (e.g., write to and/or read from) memory 62, which may comprise any kind of volatile and/or nonvolatile memory, e.g., cache and/or buffer memory and/or RAM (Random Access Memory) and/or ROM (Read-Only Memory) and/or optical memory and/or EPROM (Erasable Programmable Read-Only Memory).

Device 20 may further comprise software 66, which is stored in, for example, memory 62, or stored in external memory (e.g., database, etc.) accessible by the device 20. The software 66 may be executable by the processing circuitry 58.

The processing circuitry 58 may be configured to control any of the methods and/or processes described herein and/or to cause such methods, and/or processes to be performed, e.g., by device 20. The processor 60 corresponds to one or more processors 60 for performing device 20 functions described herein. The device 20 includes memory 62 that is configured to store data, programmatic software code and/or other information described herein. In some embodiments, the software 66 may include instructions that, when executed by the processor 60 and/or processing circuitry 58, causes the processor 60 and/or processing circuitry 58 to perform the processes described herein with respect to device 20. For example, the processing circuitry 58 of device 20 may include device unit 22 configured to perform any step and/or task and/or process and/or method and/or feature described in the present disclosure, e.g., determining one or more parameters, steps, and/or processes associated with vehicle and/or battery diagnostics. Device 20 may also include display 64 configured to display an indication associated with a measured/determined at least one parameter, e.g., associated with battery 14. The at least one parameter may include battery temperature/pressure, cell temperature/pressure, state of charge, voltage, current, etc. Display 64 may include a light such as a light emitting diode (LED), a monitor, a screen, and/or any other type of display.

In some embodiments, device 20 and/or any of its components such as display 64 may be comprised in vehicle 12 and/or BMS 16 (and/or battery 14) and/or be powered by vehicle 12 and/or BMS 16 (and/or battery 14). In some embodiments, device 20 is a computing device, a smart device or smart phone, a specialized device (e.g., provided by the manufacturer of battery 14) to remotely communicate with and/or configure BMS 16. In some other embodiments, device 20 is an on-board diagnostic (OBD) device. Further, the device 20 may be configured to perform the operations of the BMS 16 as well. Accordingly, device 20 may be configured to electrically connect to fan 54. In some other embodiments, fan 54 is comprised in battery 14. In some embodiments, fan 54 is part of BMS 16 and/or fan 54 may be connected to device 20. In some other embodiments, fan 54 is in proximity to battery 14 (e.g., the fan is in fluid communication with battery 14 but is not in direct physical contact with battery 14).

Further, server 24 includes hardware 70, and the hardware 70 may include a communication interface 72 for performing wired and/or wireless communication with BMS 16 and/or device 20 and/or any other device. For example, communication interface 72 of server 24 may communicate with communication interface 56 of device 20 via communication link 90. In addition, communication interface 72 of server 24 may communicate with communication interface 42 of BMS 16 via communication link 92. Similarly, communication interface 42 may communicate with communication interface 56 via communication link 94. At least one of communication links 90, 92, 94 may refer to a wired/wireless connection (such as WiFi, Bluetooth, etc.).

In the embodiment shown, the hardware 70 of server 24 includes processing circuitry 74. The processing circuitry 74 may include a processor 76 and a memory 78. In particular, in addition to or instead of a processor, such as a central processing unit, and memory, the processing circuitry 74 may comprise integrated circuitry for processing and/or control, e.g., one or more processors and/or processor cores and/or FPGAs (Field Programmable Gate Array) and/or ASICs (Application Specific Integrated Circuitry) adapted to execute instructions. The processor 76 may be configured to access (e.g., write to and/or read from) the memory 78, which may comprise any kind of volatile and/or nonvolatile memory, e.g., cache and/or buffer memory and/or RAM (Random Access Memory) and/or ROM (Read-Only Memory) and/or optical memory and/or EPROM (Erasable Programmable Read-Only Memory).

Thus, the server 24 further has software 80 stored internally in, for example, memory 78, or stored in external memory (e.g., database, etc.) accessible by the server 24 via an external connection. The software 80 may be executable by the processing circuitry 74. The processing circuitry 74 may be configured to control any of the methods and/or processes described herein and/or to cause such methods, and/or processes to be performed, e.g., by server 24. Processor 76 corresponds to one or more processors 76 for performing server 24 functions described herein. The memory 78 is configured to store data, programmatic software code and/or other information described herein. In some embodiments, the software 80 may include instructions that, when executed by the processor 76 and/or processing circuitry 74, causes the processor 76 and/or processing circuitry 74 to perform the processes described herein with respect to server 24. For example, processing circuitry 74 of server 24 may include server management unit 26 that is configured to perform one or more server 24 functions as described herein, e.g., determining one or more parameters, steps, and/or processes associated with battery diagnostics.

Although FIGS. 1 and 3 show one or more “units” such as BMS management unit 18, device unit 22, server management unit 26 as being within a respective processor, it is contemplated that these units may be implemented such that a portion of the unit is stored in a corresponding memory within the processing circuitry. In other words, the units may be implemented in hardware, software or in a combination of hardware and software within the processing circuitry.

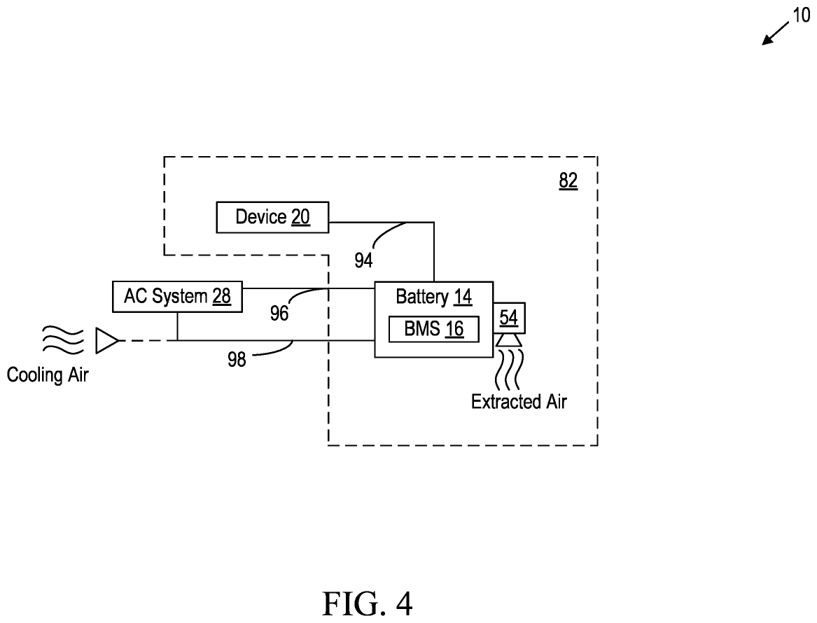

FIG. 4 shows an example system 10 according to some embodiments of the present disclosure. System 10 may include vehicle 12, battery 14, fan 54 (e.g., coupled to housing 30 of battery 14), device 20, and AC system 28. Thermal management system 82 is also shown and may include one or more components of system 10 such as battery 14, BMS 16, device 20, and fan 54. Other components of system 10 (e.g., shown in FIGS. 1-3) may be part of thermal management system 82. For example, thermal management system 82 may include one or more components of battery 14 and/or BMS 16, such as without having to include all of the components of battery 14 and/or BMS 16. Battery 14 may be in communication with device 20 (e.g., via communication link 94 and BMS 16) such as to transmit and/or receive signaling which may include control signaling, monitoring signaling (e.g., including battery information, temperature information, and/or other information), etc. Fan 54 may also be disposed proximate the housing 30 and in fluid communication with the battery 14 (and/or in fluid communication with internal spaces of battery 14). The control signaling and/or monitoring signaling associated with communication link 94 may be used to control and/or monitor device 20 and/or battery 14 (and/or BMS 16) and/or fan 54. Further, battery 14 may be in communication with AC system 28 (which may be standalone or part of vehicle 12) via communication link 96 such as to transmit and/or receive signaling which may include control signaling and/or monitoring signaling such as to control and/or monitor AC system 28 and/or battery 14 (and/or BMS 16) and/or fan 54. In addition, battery 14 may be coupled to AC line 98 (which may be referred to herein as the first AC line 98 and/or be arranged to provide cooling and/or heating to battery 14 (e.g., using a fluid). In some embodiments, AC line 98 may be a cold air line comprising cooling air usable by battery 14 to cool battery 14 (and/or any of its components) or to maintain a predetermined temperature of battery 14 (and/or any of its components). In another embodiment, AC line 98 may also be a warm air line comprising warming air usable by battery 14 to warm battery 14 (and/or any of its components) or to maintain a predetermined temperature of battery 14 (and/or any of its components).

In some embodiments, the BMS 16 may determine the temperature, which may be a predetermined functional temperature, based on one or more parameters associated with battery 14, cells 32, an exterior environment, etc. The predetermined functional temperature may refer to a temperature for which battery 14 may perform one or more functions and/or meet one or more performance requirements and/or meet a condition requirement. For example, the predetermined functional temperature may be determined such that a predetermined power requirement is met and/or a condition of a battery component is met. In a more specific example, a first predetermined temperature (T1) may correspond to a first power value (P1) (or power availability) and correspond to a first corrosion indicator (C1) indicating a corrosion level of a battery component, while a second predetermined temperature (T2) may correspond to a second power value (P2) (or power availability) and correspond to a second corrosion indicator (C2) indicating another corrosion level of the battery component. When T1 is less than T2, P2 may be greater than P1, and C1 may indicate a decrease in corrosion/decay when compared to C2.

Thus, BMS 16 may determine the functional temperature of the battery based on P1, P2, T1, T2, C1, C2, or any other parameters and establish the functional temperature as a temperature setpoint at which the battery 14 should be operated and/or perform thermal management functions using the components of system 10, thermal management system 82, or any other components described herein to make the actual battery temperature equal to the temperature setpoint (+/−a predetermined tolerance). Although two sets of parameters have been described in the example above, the embodiments are not limited as such, and any number/type of parameters may be used. In an embodiment, the predetermined functional temperature is determined based on a temperature profile that includes a plurality of temperature points (T) based on other parameters such as a plurality of power values (P) and/or corrosion indicators (C), and the predetermined functional temperature may be selected based on pre-established performance targets of the profile.

In some embodiments, the term “cool/cooling air” may refer to air having a temperature that is lower than a temperature associated with battery 14, and the term “warm/warming air” may refer to air having a temperature that is greater than the temperature associated with battery 14.

In a nonlimiting example, battery 14 receives cooling air from AC system 28 via AC line 98. Fan 54 may be turned on to extract air within battery 14 and cause cooling air in AC line 98 to enter the interior of battery 14 and/or come in contact with one or more components of battery 14, thereby cooling battery 14 (and/or any of its components). Fan 54 may be arranged to discharge extracted air to the exterior environment and/or return the air to AC system 28 such as via a return AC line (not shown). In some embodiments, the fan 54 may be energized when the battery 14 is receiving cooling air or so that the battery 14 receives cooling air. Alternatively, in other embodiments, the fan 54 may not be energized when the battery 14 is receiving cooling air or so that the battery 14 does not receive cooling air. The cooling air from the AC system 28 via AC line 98 that is discharged toward the battery 14 will be prevented from backflowing into the cabin of the vehicle 12. Put differently, the returned air does not enter the cabin of vehicle 12 or does not come in contact with air entering the cabin of vehicle 12. Once cooling air from the AC system 28 via AC line 98 is discharged toward the battery 14, there may be a mechanism in place to prevent the backflow of any solids, liquids, or gasses from the battery 14 toward the AC system 28. For example, after the cooling air from the AC system 28 via AC line 98 stops being discharged toward the battery 14, AC line 98 may have a valve (e.g. check valve) that can prevent solids, liquids, and/or gasses from flowing backwards from the battery 14 toward the AC system 28 or any other component in vehicle 12.

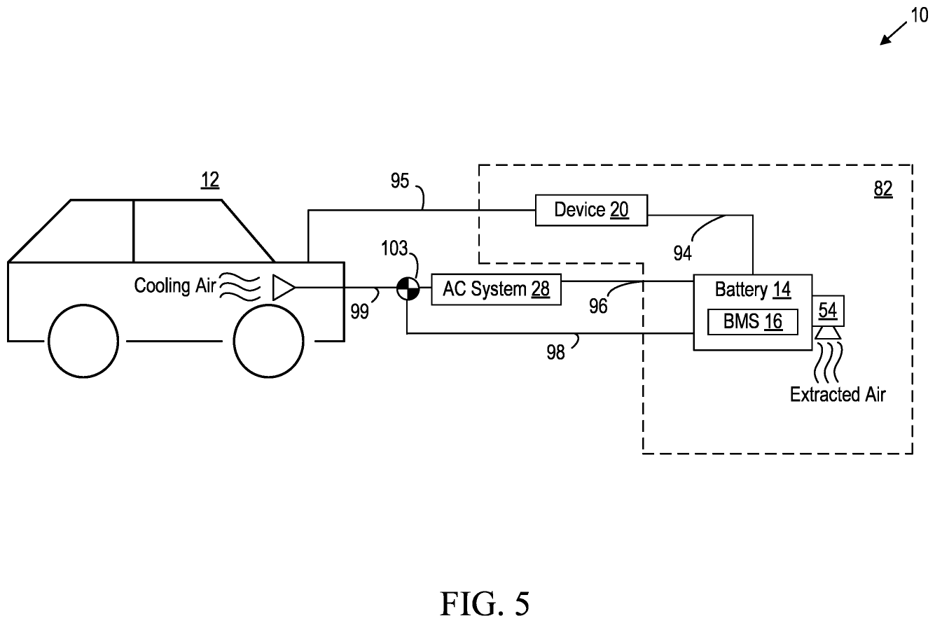

FIG. 5 shows an example system 10 according to some embodiments of the present disclosure. System 10 may include vehicle 12, battery 14, fan 54 (e.g., coupled to housing 30 of battery 14), device 20, and AC system 28. Thermal management system 82 is also shown and may include one or more components of system 10 such as battery 14, BMS 16, device 20, and fan 54. Other components of system 10 (e.g., shown in FIGS. 1-3) may be part of thermal management system 82. For example, although not shown, thermal management system 82 may include one or more components of AC System 28, communication links, AC lines, components of vehicle 12, valve 103, etc. Battery 14 may include fan 54 (e.g., coupled to housing 30) and may be in communication with device 20 (e.g., via communication link 94 and BMS 16) such as to transmit and/or receive signaling which may include control signaling, monitoring signaling (e.g., including battery information, temperature information, and/or other information), etc. Fan 54 may also be disposed proximate the housing 30 and in fluid communication with the battery 14. Also, device 20 may be in communication with the vehicle 12 (including the cabin of vehicle 12) via communication link 95 and communication link 95 may be in communication with the AC control unit inside the cabin of vehicle 12 such as to transmit and/or receive signaling which may include control signaling, monitoring signaling (e.g., including temperature information from the cabin of the vehicle, and/or other information) etc. The control signaling and/or monitoring signaling associated with communication link 94, 95 may be used to control and/or monitor device 20 and/or battery 14 (and/or BMS 16) and/or the vehicle 12 (including but not limited to the cabin of the vehicle 12) and/or fan 54. Further, battery 14 may be in communication with AC system 28 (which may be standalone or part of vehicle 12) via communication link 96 such as to transmit and/or receive signaling which may include control signaling and/or monitoring signaling such as to control and/or monitor AC system 28 and/or battery 14 (and/or BMS 16) and/or fan 54. Also, vehicle 12 may be in communication with AC system 28 (which may be standalone or part of vehicle 12) via communication link 96 such as to transmit and/or receive signaling which may include control signaling and/or monitoring signaling such as to control and/or monitor AC system 28 and/or vehicle 12. The AC system 28 may have a split such that cool air can be provided in AC line 98 toward the battery 14 and can also be provided through AC line 99 (which may also be referred to herein as a second AC line 99) toward the vehicle 12 (or vehicle cabin). The AC system 28 may supply cooling air into AC line 98 and into AC line 99 both at the same time and/or alternatively AC system 28 may supply cooling air into AC line 98 only or AC line 99 only. In one exemplary embodiment, there may be a valve 103 in a section where AC line 98 and AC line 99 connect and the valve 103 may be opened or closed to control the flow of air through AC line 98 and AC line 99. In addition, battery 14 may be coupled to AC line 98 which may be arranged to provide cooling and/or heating to battery 14. Also, the cabin of vehicle 12 or another portion of vehicle 12 may be coupled to AC line 99 which may be arrived to provide cooling and/or heating to the cabin of the vehicle 12.

In some embodiments, AC line 98 may be a cold air line comprising cooling air usable by battery 14 to cool battery 14 (and/or any of its components) or to maintain a predetermined temperature of battery 14 (and/or any of its components). In another embodiment, AC line 98 may also be a warm air line comprising warming air usable by battery 14 to warm battery 14 (and/or any of its components) or to maintain a predetermined temperature of battery 14 (and/or any of its components). Also, AC line 99 may be a cold air line comprising cooling air usable by the cabin of the vehicle 12 to cool the cabin of the vehicle 12 (and/or any other components of the vehicle 12) or to maintain a predetermined temperature of the cabin of the vehicle 12 (and/or any other components of the vehicle 12). In another embodiment, AC line 99 may also be a warm air line comprising warming air usable by the cabin of the vehicle 12 warm the cabin of the vehicle 12 (and/or any of the components of the vehicle 12) or to maintain a predetermined temperature of the cabin of the vehicle 12 (and/or any of the components of the vehicle 12).

In a nonlimiting example, the AC system 28 may have AC line 98 that can route cooling air from AC system 28 toward the battery 14 and the AC system 28 may have an entirely separate second AC line 99 that routes cooling air from AC system 28 toward the cabin of the vehicle 12. In this nonlimiting example, the cooling air from the AC system can have one AC line 98 that directly routes cooling air from the AC system 28 toward the battery 14 as well as an entirely separate and distinct second AC line 99 that routes cooling air into the cabin of the vehicle 12. Having the two separate AC lines 98, 99, can prevent the flow of any cooling air that may come into contact with the battery 14 from any air that may enter into the cabin of the vehicle 12. In this nonlimiting example, the flow of cooling air can be split between the cabin of the vehicle 12 and the battery 14 and avoid any mixing of the cooling air that is directed to the cabin and the battery 14.

Further, as a nonlimiting example, any of the cooling air from the AC system 28 via AC line 98 that is discharged toward the battery 14 will be prevented from backflowing into the cabin of the vehicle 12. Also, any of the cooling air from the AC system 28 via AC line 99 that is discharged toward the vehicle 12 will be prevented from backflowing into the battery 14. Once cooling air from the AC system 28 via AC line 98 is discharged toward the battery 14, there may be a mechanism in place to prevent the backflow of any solids, liquids, or gasses from the battery 14 toward the AC system 28. For example, after the cooling air from the AC system 28 via AC line 98 stops being discharged toward the battery 14, AC line 98 may have a valve (e.g. check valve) that can prevent solids, liquids, and/or gasses from flowing backwards from the battery 14 toward the AC system 28 or any other component in vehicle 12.

In some embodiments, BMS 16 and/or device 20 may determine that battery 14 needs to be thermally managed (e.g., a temperature exceeding a predetermined threshold or being lower than another predetermined threshold, etc.). BMS 16 and/or device 20 may transmit a control signal or indication based on the determination to AC system 28. The control signal or indication may request or indicate to any of the components of system 10 such as AC system 28 or a vehicle control system that at least some flow of air will be split between the cabin of the vehicle 12 and battery 14. The control signal or indication may trigger AC system 28 to increase blower speed to compensate for the flow of air that is diverged towards battery 14 and maintain a flow of air in the cabin. That is, the thermal management functions described herein may be performed without affecting the comfort or experience of the occupants of vehicle 12. In some other embodiments, the indication is displayed by vehicle 12 so that the occupants can increase or decrease the blower speed.

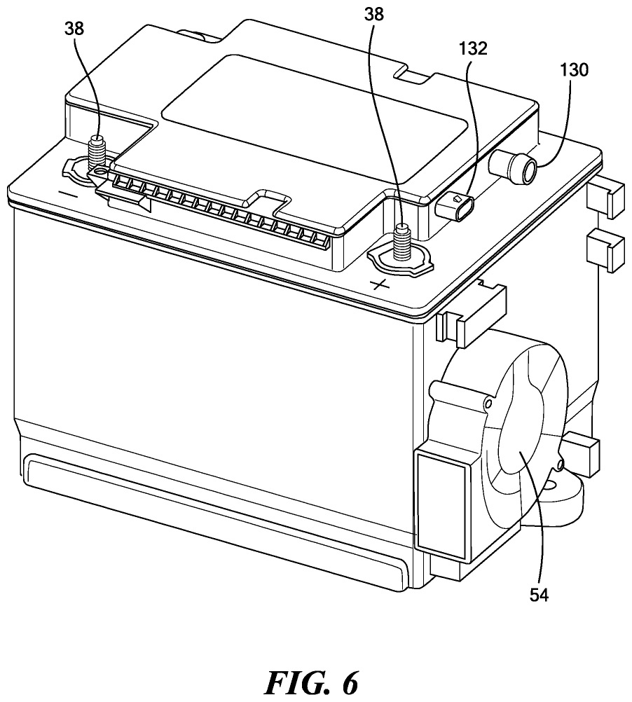

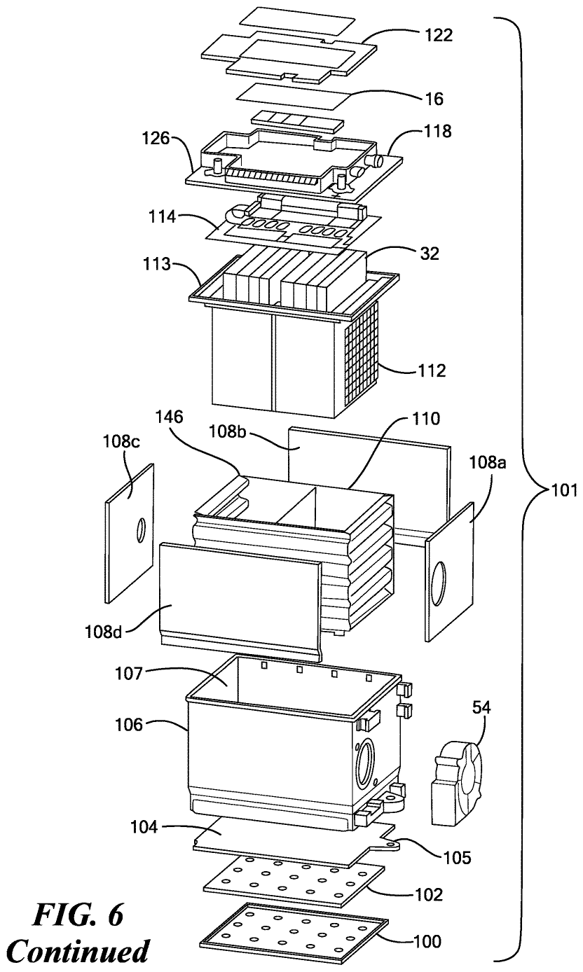

FIG. 6A shows a view of an example battery and FIG. 6B shows an exploded view of the example battery and a battery protection system 101 according to some embodiments of the present disclosure. Battery 14 may include one or more of the following: bottom cover 100, isolation layer 102 (e.g., Polyethylene Foam (PE) foam which may also be referred to as base layer 102), base plate 104 (e.g., steel base plate), fan 54, battery housing 106 (which may be the same as housing 30 and/or be a base housing made of plastic), isolation layers 108a, 108b, 108c, and 108d (collectively referred to as “108” and which may also be referred to as second layer 108) (e.g., PE foam), cell housing box 110 (e.g., cell swelling resistor (CSR) crash box which may be made of metal), cell housing 112 (e.g., CSR which may be made of plastic), cells 32, bus carrier (B-carrier) 114, e-carrier 118 (e.g., which may be made of plastic), BMS 16 (e.g., BMU and/or bus bars), and cover 122.

In a nonlimiting example, the cell housing 112 may seal to a portion of the battery housing 106. The cell housing 112, which houses the battery cells 32, may include an extended portion 113 which extends outwardly from the cell housing 112. The extended portion 113 of the cell housing 112 may be coupled with a first portion 107 the battery housing 106 such that the extended portion 113 seals with the first portion 107 of the battery housing 106. Accordingly, when the cell housing 112 extended portion 113 is placed within the battery housing 106, the first portion 107 of the battery housing 106 may be sealed with the cell housing 112 extended portion 113 so that the cells 32 that are within the cell housing 112 are within a separate air space that is formed when the cell housing 112 is placed within the battery housing 106. This separate air space allows cooling air to more efficiently and effectively cool the battery 14 when cooling air is directed from the AC system 28 toward the battery 14. Similarly, this separate air space allows warming air to more efficiently and effectively heat the battery 14 when warming air is directed from the AC system 28 toward the battery 14.

Isolation layers 102, 108 may be an insulator and isolation layer 102, 108 may be made from insulating materials. These insulating materials may include, but not be limited to fiberglass, mineral wool, cellulose, natural fibers, polystyrene, polyisocyanurate, polyurethane, perlite, cementitious foam, phenolic foam, and insulation facings. Also, Isolation layer 102, 108 may block and/or slow the movement of heat that is created by battery 14 when battery 14 is in close proximity with isolation layers 102, 108. Furthermore, having isolation layer 102 placed prevents heat from the battery 14 from getting to the bottom cover 100. Having a bottom cover 100 that does not get too warm is particularly important when the battery 14 is in place in vehicle 12 as battery 14 can be in close proximity to and/or in contact with certain parts of the vehicle 12 including the chassis.

Although isolation layers 102 and 108 have been described together as an insulator and isolation layer 102, 108, it will be understood that isolation layers 102 and 108 are components that may be independent of one another of the battery protection system 101. Alternatively, isolation layers 102, 108 may also be components that are not independent of one another in the battery protection system 101.

In a nonlimiting example, the base plate 104 may be made from a metal including steel and the base plate 104 may further include at least one tab 105. The at least one tab 105 may assist with the installation process so that the base plate 104 can be easily secured in place by using the at least one tab 105. The base plate 104 may further protect the battery 14 when the base plate 104 is in close proximity to the battery 14. The base plate 104 may have a thickness of between 3 and 3½ millimeters. If the base plate 104 is met with a force, the thickness of the base plate 104 along with the material that the base plate 104 is made out of can provide protection to the battery 14.

In one embodiment, the battery protection system 101 may include isolation layer 102. For example, isolation layer 102 may be disposed and/or coupled to the bottom surface of the battery housing 106. Isolation layer 102 may be directly coupled with the base plate 104 and the base plate 104 may be coupled with the battery housing 106 thereby providing protection against impact by base plate 104 and isolation layer 102 as well as accompanying thermal management functions in this configuration. In another embodiment, the battery protection system 101 may include isolation layer 108 that may at least partially surround the cell housing box 110 and both the isolation layer 108 and the cell housing box 110 may be inserted into the battery housing 106. This configuration may provide protection against impact by isolation layer 108 and the cell housing box 110 as well as accompanying thermal management functions. In some other embodiments, the battery protection system 101 may include isolation layers 102 and 108 and in this non-limiting configuration isolation layers 102 and 108 do not come in direct contact with one another.

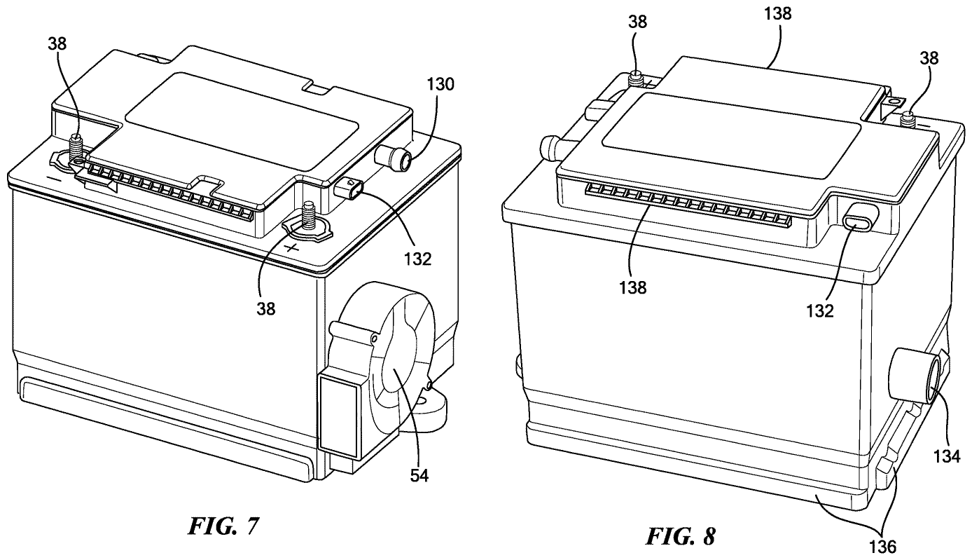

FIG. 7 shows a perspective view of an example battery 14 according to some embodiments of the present disclosure. Battery 14 may include terminals 38 (e.g., main terminals comprising a stud such as an M8-sized stud), vent port 130 (arranged to release gas from within battery 14), fan connector 132, and fan 54. Fan connector 132 may be arranged to electrically connect to fan 54 (and/or BMS 16), e.g., via a cable (not shown) external to battery 14 and via one or more conductors to BMS 16. Vent port 130 may be arranged to discharge gases contained in a space that is in fluid communication with battery cells 32 and BMS 16. The space may be defined by cell housing 112 and cover 122. The gases may be discharged to the exterior of the battery via vent port 130 such as when the internal pressure in such space exceeds a predetermined threshold. The gases within the space or that are discharged do not come in contact with the air that enters the battery 14 for thermal management of the battery 14. That is, the components of battery 14 are arranged in a manner that prevents the gases (contained in the space that houses battery cells 32 and/or BMS 16 or that is discharged through vent port 130) from contacting or mixing with the fluid that is used for thermal management of the battery 14. Further, the battery protection system 101 may also include cover 126 and cover 126 may be sized and shaped to receive at least BMS 16. Additionally, cover 122 and cover 126 may be coupled to each other (directly/indirectly) and provide an internal space for venting gases to pass through and leave battery 14 via vent port 130.

FIG. 8 shows another perspective view of an example battery according to some embodiments of the present disclosure. Battery 14 includes monitoring connector 34 (e.g., 3-pin connector) configured to provide communication between battery 14 and vehicle 12 (e.g., via device 20). Battery 14 may further include lifters 138 (e.g., for battery handling) and hold-downs 136 (e.g., to secure battery 14 to another component such as a tray). Battery 14 may include air inlet 134 in fluid communication with an interior space of battery 14 to receive cooled air via an AC vent line such that when fan 54 is energized air from the AC line flows through the interior space of the battery 14 and is extracted out to the exterior of battery 14, thereby cooling/heating the battery 14. Once the air is extracted out to the exterior of the battery 14, the air may exist through the vent port 130.

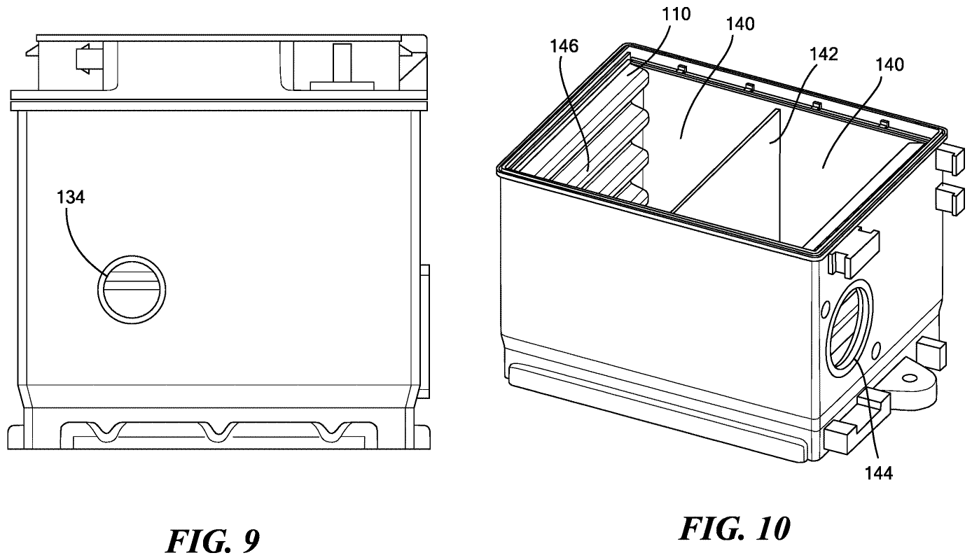

FIG. 9 shows a side view of an example battery 14 according to some embodiments of the present disclosure. The battery 14 may be contained within battery protection system 101 and air inlet may be in communication with a portion of the inside of the battery protection system 101. When the battery 14 is contained within the battery protection system 101, the battery protection system 101 may prevent the deformation of the battery if the battery 14 is impacted by forces such as a vehicle collision or other impact with the vehicle 12. Also, when the battery 14 is contained within the battery protection system 101, the battery protection system 101 may prevent any puncturing of the battery from outside sources. For example, if the battery (14) or the area around the battery is impacted and/or impaled by a foreign object such as another vehicle or an object on the road, the battery protection system 101 may prevent the battery from being punctured by the outside objects. Further, when the battery 14 is contained within the battery protection system 101, the battery protection system 101 may prevent movement of the battery 14 when the battery 14 is contained and secured within the various components of the battery protection system 101. When the battery is impacted by an outside source, the battery protection system 101 will receive and disperse the forces from the impact so that the battery 14 is secured within the battery protection system 101.

FIG. 10 shows an example battery housing 106 according to some embodiments of the present disclosure. Battery housing 106 may include one or more compartments 140, which may be divided by divider 142. Battery housing 106 may also include one or more components of cell housing box 110 (e.g., corrugated panel). Having the cell housing box 110 with at least a portion of the cell housing box 110 with a corrugated panel allows for additional and/or controlled surface area (when compared to non-corrugated panels) for improved thermal management. For example, when battery cells 32 are placed within the cell housing box 110, battery cells 32 may directly/indirectly contact the corrugated panel. As the air flows between ridges of the corrugated panel, the corrugated panel may be cooled or heated, consequently cooling or heating the battery cells 32. The corrugated pattern of the corrugated panel may also provide a mechanism for controlling to which area of the battery cells 32 to direct the cooling or heating effect. For example, the area where the ridges contact compartments/dividers 152 may be cooled or heated faster than those areas that areas not in direct contact with the ridges.

Also, the corrugation of the panels in the cell housing box 110 further provide additional rigidity and strength to the cell housing box 110. It will be understood that cell housing box 110 may include one side or a plurality of sides with corrugation. As a non-limiting example, the cell housing box 110 may have 3 sides that are corrugated and one side that has a smooth surface. Alternatively, all sides of the cell housing box 110 may be corrugated or less than all the sides may be corrugated. These corrugations add extra points of rigidity and prevent bending and/or sagging of the cell housing box 110 under tensile and compressive forces. These ridges and grooves 146 create a wavy and/or ribbed appearance which increases the surface area with the use of the ridges and grooves 146. Specifically, the ridges and grooves 146 act as stiffeners and increase the strength by distributing weight more evenly over a larger area. Also, the ridges and grooves 146 are more resistant to deformation and have a greater ability to support weight. Using the corrugated panel in the cell housing box 110 provides additional crash protection to the battery 14 when the battery is contained within the cell housing box 110. For example, if the battery 14 is within a vehicle 12 and the vehicle 12 is in some type of accident, the cell housing box 110 will be able to withstand additional forces and provide protection to battery 14. Opening 144 may be arranged to receive and couple fan 54 or a hood any of which may be arranged to release air from within battery 14.

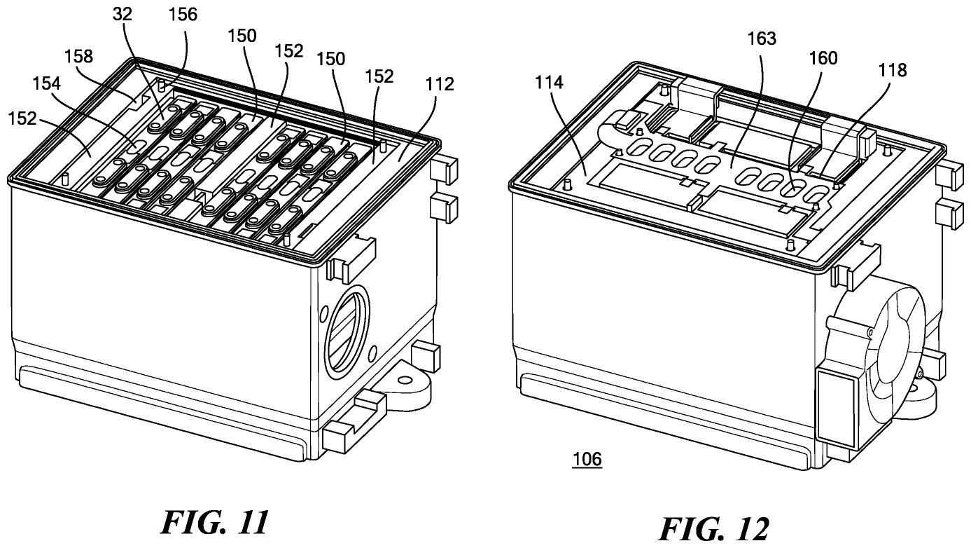

FIG. 11 shows an example battery housing 106 comprising cell housing 112 and cells 32 according to some embodiments of the present disclosure. Cell housing 112 may comprise cell housing compartments 150 which may be separated by dividers 152. The cell housing compartments 150 may be arranged to receive cells 32 in an internal space of the cell housing compartments 150. Each one of the cells 32 may include a cell vent 154 arranged to vent gas from an interior space of the corresponding cell 32.

FIG. 12 shows an example battery housing 106, cell housing 112, cells 32, and bust bar/bus carrier (B-carrier) 114 according to some embodiments of the present disclosure. Bus bar 114 may include vent openings 160 (e.g. aligned with corresponding cell vents 154) and printed board 163 (configured to connect to one or more components of BMS 16 and/or battery 14). Vent openings 160 may be in fluid communication with the internal space of compartments 140, battery cells 32, etc. and be arranged to provide a path for the gas contained within the internal space to be discharged from the battery 14. Also, there may be at least one protrusion 156 on the dividers 152. The at least one protrusion 156 may provide support and/or spacing between the cover 122 and/or the cells 32. The dividers 152 may also include at least one aperture 158 and the at least one aperture 158 may be sized and shaped to provide routing of the e-carrier 118 to other section of the battery 14. In the non-limiting example as shown in FIG. 11, the aperture 158 may route the e-carrier 118 to the sections of the battery 14 which are contained within the battery housing 106. Also, BMS 16 may be connected to printed board 163 and provide a space between the bus bar 114 and the BMS 16 (e.g., to provide fluid communication with cell vents 154, vent openings 160 and interior of cells 32 (e.g., when cell vents 154 are open).

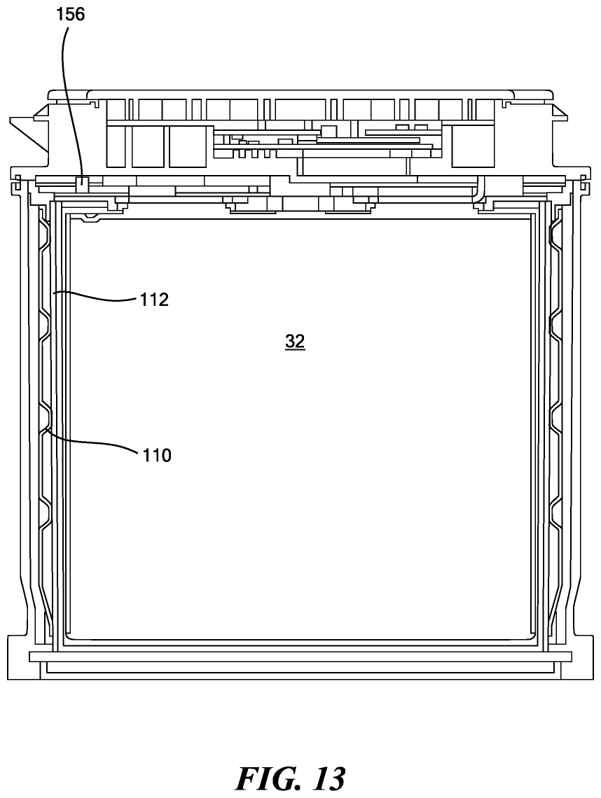

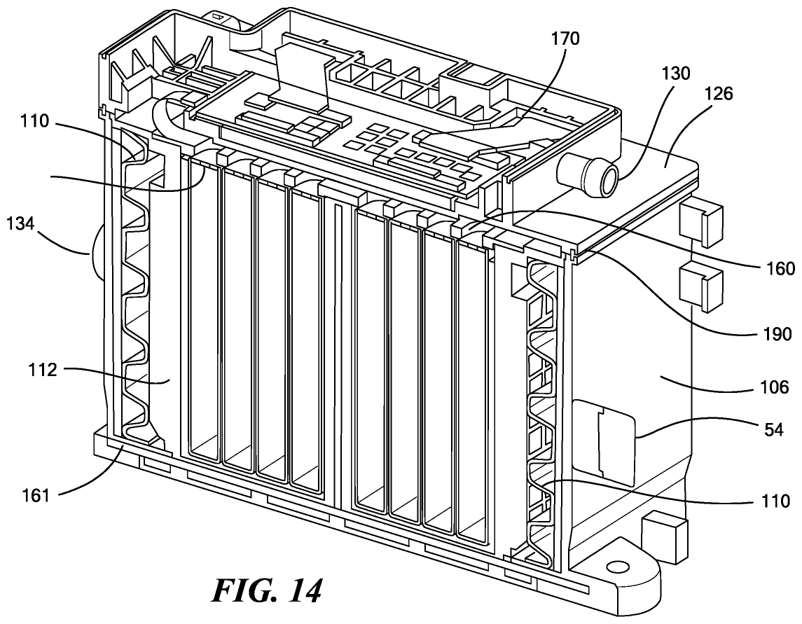

FIG. 13 shows a cross section view of an example battery 14 including battery cells 32 according to some embodiments of the present disclosure Now referring to FIG. 14, The cells 32 may include cell vent 154 which may be sealed to and/or in fluid communication with vent opening 160. Vent opening 160 is in fluid communication with the internal space 161 defined by the covers 122, 126 and in fluid communication with vent port 130. Battery 14 may include air inlet 134 and fan 54 which is arranged to extract air from within battery 14 and cause air (e.g., cooling air) to enter the internal space of the battery. Battery 14 comprises air inlet 134 and fan 54, where fan 54 is arranged to extract air in an internal space 161 of the battery 14 (e.g., the internal space between cell housing 112 and battery housing 106. The internal space may include one or more components of cell housing box 110 (e.g., corrugated panels). The internal space may include any other spaces within battery housing 106. In one nonlimiting example, when fan 54 is on, air in the internal space is extracted and cooling air entering the air inlet 134 is suctioned into the internal space, thereby cooling battery components such as cells 32, BMS 16, etc. In a nonlimiting example, air inlet 134 may be connected to AC line 98 which can provide cooling air and/or warming air from AC system 28 when AC system 28 is activated. In another nonlimiting example, the cooling air in the internal space serves as thermal barrier between the exterior and battery components (e.g., heat from the exterior is prevented from being absorbed by the components of battery 14). In some embodiments, fan 54 is energized (e.g., by BMS 16 via fan connector 132 (and a cable connecting fan connector 132 and fan 54) based on a battery parameter (e.g., temperature, pressure of cells or battery) and/or the temperature outside of the battery 14 (e.g., within engine compartment of vehicle 12) and/or information about AC system 28 (e.g., compressing, blowing, cooling, heating) and/or device 20 and/or vehicle 12 such as ignition status and/or AC cooling status.

Further, battery 14 may provide venting features. More specifically, cell vents 154 may be sealed to and/or in fluid communication with vent opening 160 and internal space 170 (e.g., defined by the covers). Vent opening 160 may be in fluid communication with the internal space 170 and in fluid communication with vent port 130.

In some embodiments, the venting features and the cooling/heating features are separate. That is, air entering battery via air inlet 134 and leaving the battery 14 via fan 54 does not contact or mix with any of the vent gases and/or internal space 170. In some other embodiments, air inlet 134 (and/or AC line 98 and/or fan 54) includes one or more valves arranged to control flow of air (e.g., cooling air) and/or prevent air to return to AC system 28 and/or vehicle 12 (e.g., cabin) via AC line 98. In some embodiments, the valves are check valves.

In some other embodiments, IR Guide welding is used to join (i.e., couple) battery housing 106, cell housing 112, and cover 126 such as at edge 190. Coupling these components may provide sealing features for venting gases (i.e., the internal space 170 may further be defined by the coupling of battery housing 106, cell housing 112, and cover 126 such as at edge 190) and for separating air for cooling/heating from vent gases.

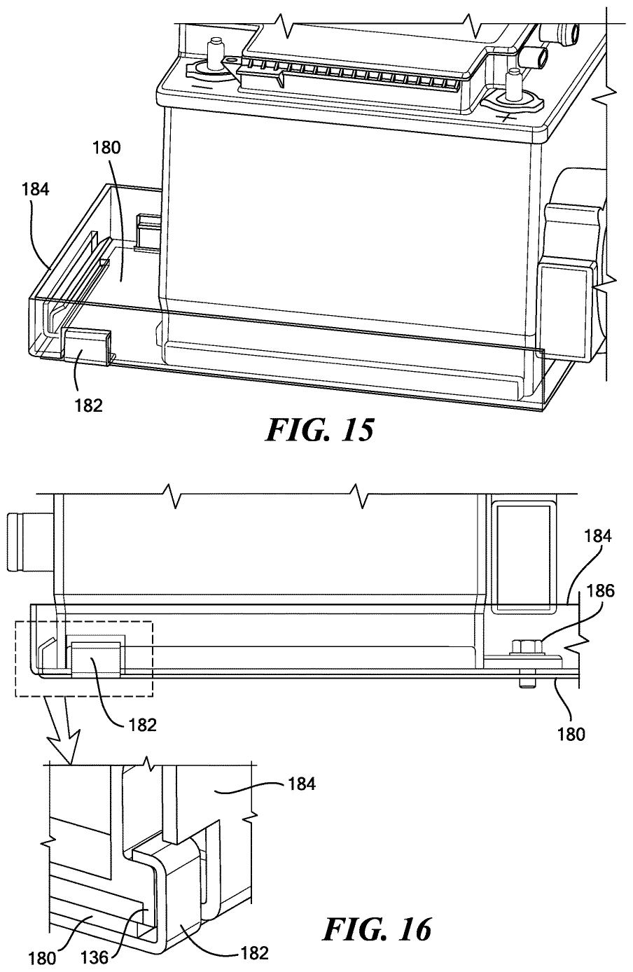

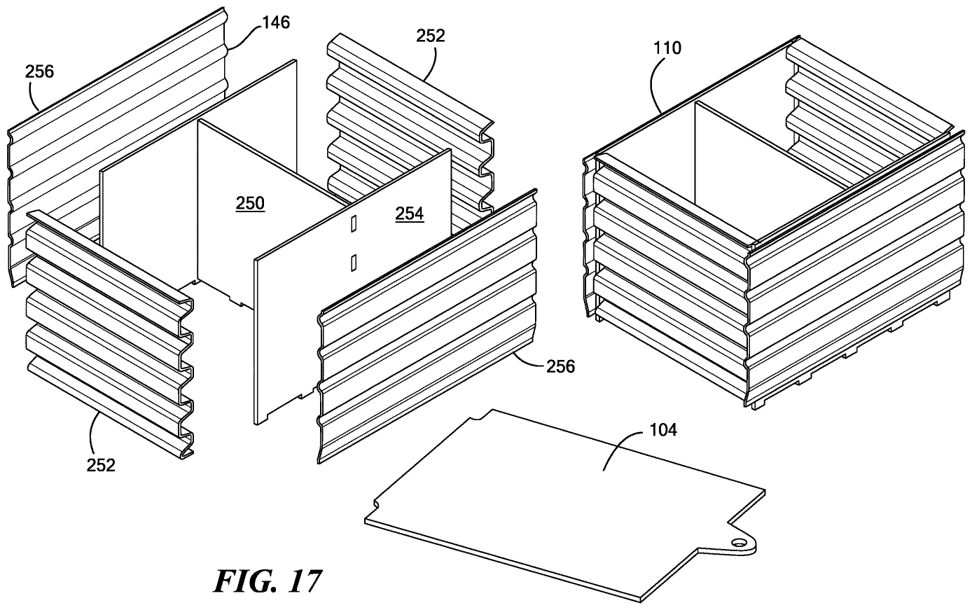

FIG. 15 shows an example battery 14, tray plate 180, tab 182, and tray 184 according to some embodiments of the present disclosure. Tray 184 may receive (or be received by) tray plate 180. Tray plate 180 may include one or more tabs arranged to couple to a bottom portion of battery 14 and secure battery 14 onto tray 184. FIG. 16 shows a section of an example battery 14 and tray according to some embodiments of the present disclosure. Battery 14 may further be coupled to tray plate 180 (and/or tray 184) via fastener 186. Tab 182 is coupled to hold-down 136 and exerts a force in the direction of the battery bottom to hold down and secure battery 14 to tray plate 180 and tray 184.

Battery 14 includes one or more of the following: cover, isolation layer, base plate, battery housing (which may be the same as housing 30), isolation layers, cell housing box, cell housing, e-carrier, and cover.

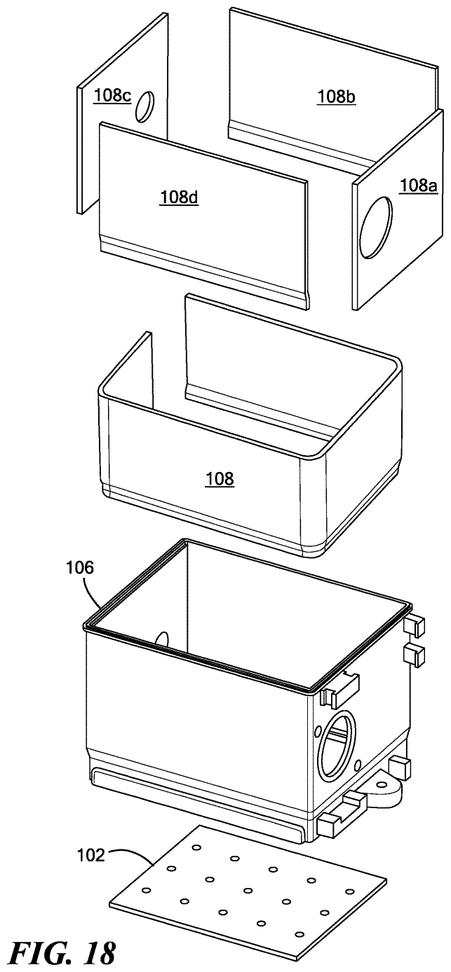

FIG. 17 shows an example cell housing box 110 according to some embodiments of the present disclosure. Cell housing box 110 may include one or more components such as sheet 250, sheet 252, sheet 254, sheet 256, and base plate 104 any of which can be made of metal or any other type of material. Sheets 250, 254 may be arranged as a compartment structure to separate groups of cells 32 from the battery 14 such as when cell housing 112 is received within cell housing box 110. Sheets 252, 256 may be ridged (e.g., corrugated, wavy) and be arranged for passage of air such as cooling air entering the air inlet 134. Also, sheets 252, 256 may provide additional protection to the battery 14 when it is contained within the cell housing box 110. Sheets 252, 256 may also have one sheet or more than one sheet that does not have ridges and grooves 146 and may be a flat or otherwise textured surface. Further, sheets 252, 256 may be assembled together and coupled to sheets 250, 254 as shown. In some embodiments, when air (e.g. cooling air) contacts sheets 252, 256, a thermal exchange occurs. For example, cooling air passing through the internal space of battery 14 comes in contact at least with sheets 252, 256 and cools sheets 252, 256 which in turn can cool other components such as sheets 250, 254, cell housing 112, cells 32, base plate 104, and other battery components. In some embodiments, the air directly/indirectly cools other battery components.

In addition, cell housing box 110 may be arranged to provide crush protection features. For example, any of sheets 250, 252, 254, 256 may be arranged to absorb energy from an impact without deforming beyond a deformation threshold. In other words, cell housing box 110 is one of the components of battery 14 that is arranged to provide protection to battery 14 from crushing forces such as when a vehicle is involved in accident. Having the cell housing box 110 with at least a portion of the cell housing box 110 with a corrugated further provide additional rigidity and strength to the cell housing box 110. These corrugations add extra points of rigidity and prevent bending and/or sagging of the cell housing box 110 under tensile and compressive forces. These ridges and grooves 146 create a wavy and/or ribbed appearance which increases the surface area with the use of the ridges and grooves 146. Specifically, the ridges and grooves 146 act as stiffeners and increase the strength by distributing weight more evenly over a larger area. Also, the ridges and grooves 146 are more resistant to deformation and have a greater ability to support weight. Using the corrugated panel in the cell housing box 110 provides additional crash protection to the battery 14 when the battery 14 is contained within the cell housing box 110. For example, if the battery 14 is within a vehicle 12 and the vehicle 12 is in some type of accident, the cell housing box 110 will be able to withstand additional forces and provide protection to battery 14.

Further, cell housing box 110 may be arranged to provide containment features. For example, cell housing box 110 may be arranged to provide a predefined volume or fixed volume to hold components and prevent the components (e.g., cells 32) from swelling beyond the predefined volume. In some embodiments, cell housing box 110 may be a rigid structure that provides crush protection and anti-swelling features.

FIG. 18 shows an exploded view of an example battery housing 106 and isolation layers 108 according to some embodiments of the present disclosure. Battery housing 106 includes isolation layer 108 which is shown contained within battery housing 106. Isolation layers 108 may include a plurality of isolation layers 108 where one or more isolation layer 108 is coupled to two other isolation layers 108, or a single isolation layer 108 of a single unitary construction. It will be understood that there may be a plurality of isolation layers 108 that may be included within the battery housing 106 and/or there may be a unitary piece which is the isolation layer 108. Isolation layers 108 may be arranged as an isolation layer between battery housing 106 and other components contained within the battery housing 106 such as cell housing box 110. Further, isolation layer 102 may be positioned between base plate 104 and bottom cover 100.

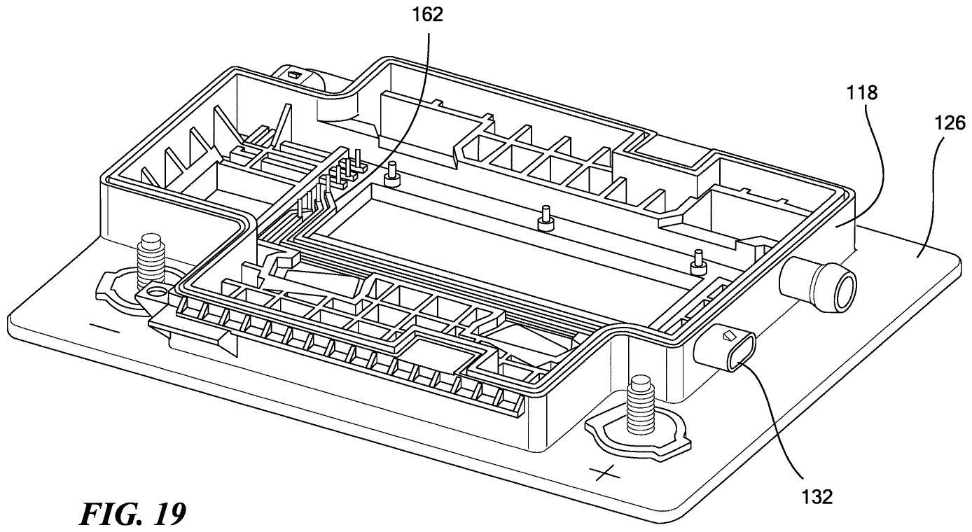

FIG. 19 shows an example cover 126 and components according to some embodiments of the present disclosure. Cover 126 may include e-carrier (i.e., electronics carrier) 118 which may comprise an internal space such as for venting and for housing one or more electronic components such as BMS 16, conductors 162. The first end of each one of conductors 162 are positioned within fan connector 132. In some embodiments, fan connector 132 comprises connector pins, and the first end of each conductor 162 may be coupled to a corresponding pin. The pins may be connected to conductors of a cable that is connected to fan 54. The second end of each one of conductors 162 may be connected to BMS 16. In other words, the BMS 16 may be electrically connected to fan 54 via conductors 162, fan connector 132 (and/or its pins), a cable electrically coupled to fan 54. One or more conductors 162 may be arranged for providing power to fan 54. One or more conductors 162 may be arranged to provide control/monitoring signaling such as to monitor and/or control fan 54. In some embodiments, fan 54 and/or BMS 16 and/or any other battery components may be powered using the power provided by terminals 38 and terminal conductors 162. For example, if terminals 38 provide 12V, fan 54 may be powered using 12V (or a different voltage) via terminal conductors 162, fan connector 132, etc. Further, additional conductors may be provided for communication with vehicle 12 and/or device 20 and/or any other component.

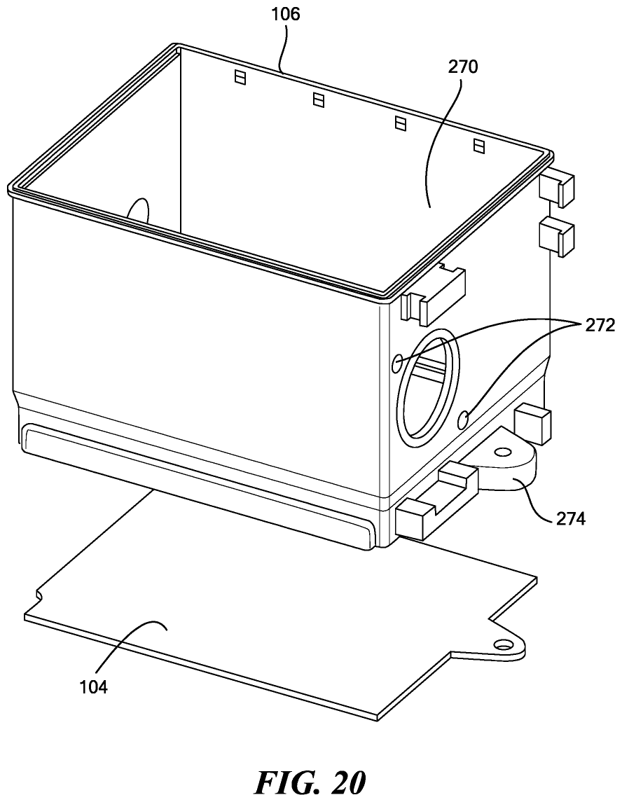

FIG. 20 shows an example battery housing 106 according to some embodiments of the present disclosure. For example, battery housing 106 may be provided without base plate 104 or with base plate 104. Further, battery housing 106 may also include CSR holding features 270, fasteners 272 (e.g., insert nuts which may be used to couple fan 54 to battery housing 106), and metal spacer 274 which may be arranged for creating a space between battery housing 106 and a tray.

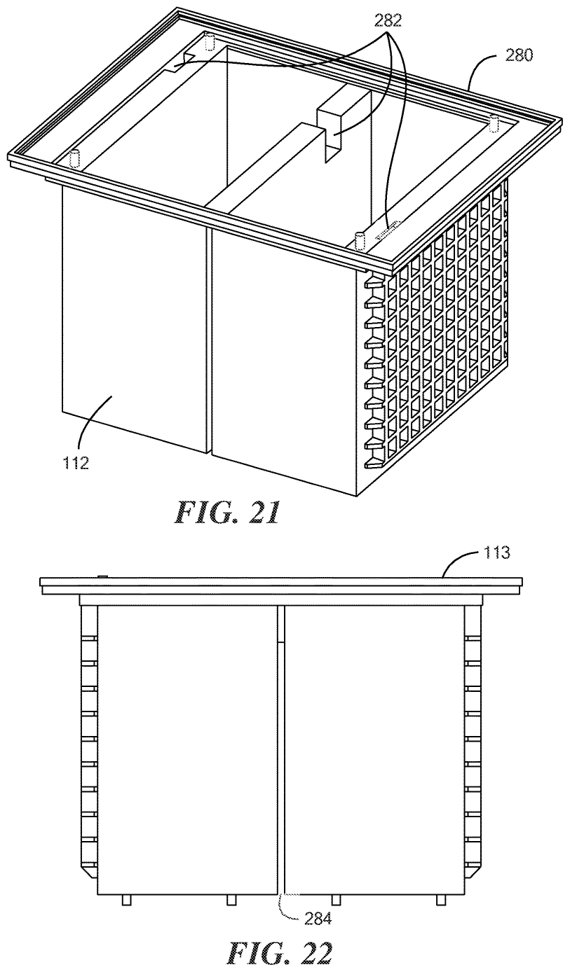

FIG. 21 shows a perspective view of an example cell housing 112 according to some embodiments of the present disclosure. Cell housing 112 may comprise one or more openings 282 (e.g., t-sense openings) which may be configured to provide space for one or more elements arranged for measurement of one or more parameters (e.g., battery temperature, cell temperature, cell housing temperature, pressure, etc.) In some embodiments, the measurements are performed directly on and/or in the one or more openings 282. In some other embodiments, the one or more openings 282 provide a space for routing the elements, where the elements may measure a parameter of a component not directly within the space provided by the openings 282. In one example, a thermocouple component may measure the temperature at opening 282 or be routed through the opening 282 to measure the temperature of a cell 32 housed within cell housing 112 or a specific area within the cell housing 112 depending upon the location of the thermocouple component. Welding edge 280 (e.g., welding line) may be arranged for IR guide welding which provides coupling of three components (e.g., cover 126, battery housing 106, and cell housing 112).

FIG. 22 shows a side view of the example cell housing 112. Further, as can be seen in FIG. 22, the cell housing 112 may include a space 284 so that the cell housing 112 may be placed in the battery housing 106 and the space 284 may be sized to fit between the divider 142 and the extended portion 113 of the cell housing 112 may be larger than the cell housing box 110 so that when the cell housing 112 is placed within the cell housing box 110, the extended portion 113 is not received within the cell housing box 110.

In one or more embodiments, thermal management system 82 shown in FIGS. 4 and 5 may include any of the components and elements shown in FIG. 6A. 6B and 7-22. For example, any of the components shown in FIGS. 6A and 6B may be comprised in thermal management system 82, such as bottom cover 100, isolation layer 102, base plate 104, fan 54, battery housing 106, isolation layer 108, cell housing box 110, cell housing 112, BMS 16, and cover 122. More specifically, air from AC system 28 may be routed through any of the components of battery 14 such as air inlet 134, ridges and grooves 146, opening 144, fan 54, etc. to perform thermal management of battery 14 (e.g., cooling/heating battery 14, maintaining a predetermined temperature of battery 14 or any of its components). In some embodiments, thermal management system 82 may be used in conjunction with crush protection components or containment component such as components of the present disclosure that may be used protect a battery 14 during an impact or any other event.

In some embodiments, battery 14 is an H6 footprint 50 Ah battery arranged to provide power to an internal combustion engine (ICE) vehicle. Battery 14 includes fan 54 such as a forced air cooling fan for providing thermal control features (e.g., cooling) to battery 14. Further, battery 14 via one or more components such as those shown in FIGS. 6-22 provide crush protection. In some embodiments, battery 14 is positioned within the engine compartment of vehicle 12. In this position, battery 14 may be susceptible to environmental heating and cooling as well as heating and cooling from various components of vehicle 12 as well.

Battery 14 may be arranged to provide at least one of the following benefits: (A) vent gas and cooling air separation; (B) combined crush and cell swelling protection; and (C) IR guide welding of cover and plastic CSR into mid-cover. For example, if gas is vented from cells 32, the gas is kept separate from the cooling air (incoming through air inlet 134). The separation is beneficial at least because the cooling air may be coming from the cabin of vehicle 12. That is, the features of battery 14 include separation of cooling and venting such that unsafe gases are prevented from penetrating the cabin and gas that is vented from cells 32 is not moved and/or shared with the cabin of vehicle 12.

In addition, a plastic cell swelling restraint may be provided by components such as cell housing 112 which may be combined with cell housing box 110 (e.g., steel crash cage) and base plate 104 (e.g., steel bottom plate) to provide resistance to cell swelling and crushing forces. Further, IR Guide welding provides coupling of three components (e.g., cover 126, battery housing 106, and cell housing 112,) as shown by edge 190 of FIG. 15.

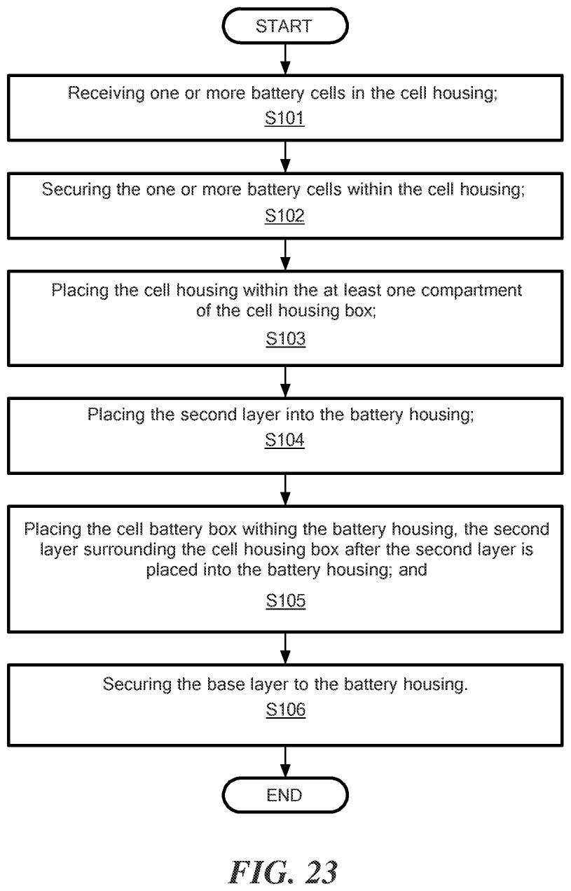

Now referring to FIG. 23, a method for securing a battery 14 is described. The battery 14 includes one or more battery cells 32 and a battery protection system 101 for protecting at least the one or more battery cells 32. The battery protection system 101 may include a base layer 102, a battery housing 106, a second layer 108, a cell housing box 110, and a cell housing 112. The second layer 108 may be sized to be received within the battery housing 106. The cell housing box 110 may have at least one compartment and the at least one compartment may be sized to releasably receive the cell housing 112. The method may include receiving the one or more battery cells 32 in the cell housing 112 (S101). The method may further include securing the one or more battery cells 32 within the cell housing 112 (S102); and placing the cell housing 112 within the at least one compartment of the cell housing box 110 (S103); and placing the second layer 108 into the battery housing 106 (S104). The method may also include placing the cell housing box 110 within the battery housing 106, the second layer 108 surrounding the cell housing box 110 after the second layer 108 is placed into the battery housing 106 (S105); and securing the base layer 102 to the battery housing 106 (S106).

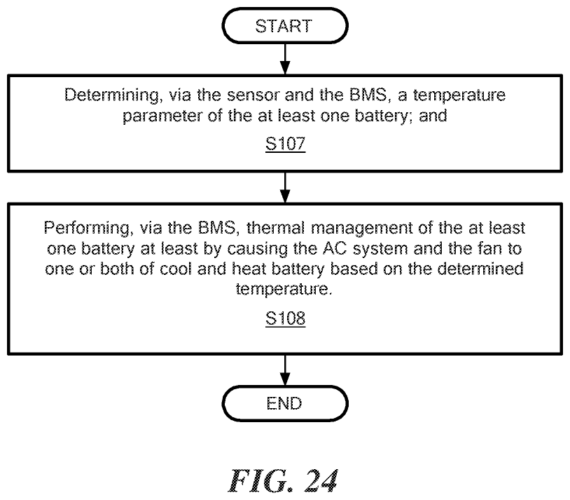

Now referring to FIG. 24, a method thermally managing a battery 14 is described. The method is implemented by a thermal management system 82 associated with at least one battery 14 and having a fan 54 that is proximate the battery 14 and in fluid communication with the battery 14. The thermal management system 82 has a sensor 45 configured to measure a temperature of the of the at least one battery 14 and a BMS 16 in communication with the sensor 45 and the fan 54. The thermal managing system 82 is associated with a vehicle 12 having an air conditioning, AC, system 28 in fluid communication with the battery 14. The method may include determining, via the sensor 45 and the BMS 16, a temperature parameter of the at least one battery 14 (S107). The method may further include performing, via the BMS 16, thermal management of the at least one battery 14 at least by causing the AC system 28 and the fan 54 to one or both of cool and heat battery 14 based on the determined temperature (S108).

As will be appreciated by one of skill in the art, the concepts described herein may be embodied as a method, data processing system, computer program product and/or computer storage media storing an executable computer program. Accordingly, the concepts described herein may take the form of an entirely hardware embodiment, an entirely software embodiment or an embodiment combining software and hardware aspects all generally referred to herein as a “circuit” or “module.” Any process, step, action and/or functionality described herein may be performed by, and/or associated to, a corresponding module, which may be implemented in software and/or firmware and/or hardware. Furthermore, the disclosure may take the form of a computer program product on a tangible computer usable storage medium having computer program code embodied in the medium that can be executed by a computer. Any suitable tangible computer readable medium may be utilized including hard disks, CD-ROMs, electronic storage devices, optical storage devices, or magnetic storage devices.

Some embodiments are described herein with reference to flowchart illustrations and/or block diagrams of methods, systems and computer program products. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer (to thereby create a special purpose computer), special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable memory or storage medium that can direct a computer or other programmable data processing apparatus to function in a particular manner, such that the instructions stored in the computer readable memory produce an article of manufacture including instruction means which implement the function/act specified in the flowchart and/or block diagram block or blocks.

The computer program instructions may also be loaded onto a computer or other programmable data processing apparatus to cause a series of operational steps to be performed on the computer or other programmable apparatus to produce a computer implemented process such that the instructions which execute on the computer or other programmable apparatus provide steps for implementing the functions/acts specified in the flowchart and/or block diagram block or blocks.

It is to be understood that the functions/acts noted in the blocks may occur out of the order noted in the operational illustrations. For example, two blocks shown in succession may in fact be executed substantially concurrently or the blocks may sometimes be executed in the reverse order, depending upon the functionality/acts involved. Although some of the diagrams include arrows on communication paths to show a primary direction of communication, it is to be understood that communication may occur in the opposite direction to the depicted arrows.

Computer program code for carrying out operations of the concepts described herein may be written in an object oriented programming language such as Python, Java® or C++. However, the computer program code for carrying out operations of the disclosure may also be written in conventional procedural programming languages, such as the “C” programming language. The program code may execute entirely on the user's computer, partly on the user's computer, as a stand-alone software package, partly on the user's computer and partly on a remote computer or entirely on the remote computer. In the latter scenario, the remote computer may be connected to the user's computer through a local area network (LAN) or a wide area network (WAN), or the connection may be made to an external computer (for example, through the Internet using an Internet Service Provider).

Many different embodiments have been disclosed herein, in connection with the above description and the drawings. It will be understood that it would be unduly repetitious and obfuscating to literally describe and illustrate every combination and subcombination of these embodiments. Accordingly, all embodiments can be combined in any way and/or combination, and the present specification, including the drawings, shall be construed to constitute a complete written description of all combinations and subcombinations of the embodiments described herein, and of the manner and process of making and using them, and shall support claims to any such combination or subcombination.

It will be appreciated by persons skilled in the art that the present embodiments are not limited to what has been particularly shown and described herein above. In addition, unless mention was made above to the contrary, it should be noted that all of the accompanying drawings are not to scale. A variety of modifications and variations are possible in light of the above teachings and the following claims.

1. A thermal management system associated with a vehicle and at least one battery, the vehicle having an air conditioning, AC, system with a first AC line and a first communication link, the AC system being in fluid communication with the battery through the first AC line and in electrical communication with the battery through the first communication link, the thermal management system comprising:
a fan that is in fluid communication with the at least one battery;
a sensor configured to measure a temperature of the of the at least one battery;
a battery management system, BMS, in communication with the sensor and the fan, the BMS being configurable to be in communication with the AC system, the BMS being configured to:
determine, via the sensor, the temperature of the at least one battery; and
perform thermal management of the at least one battery at least by causing the AC system and the fan to one or both of cool and heat the at least one battery based on the determined temperature.

2. The thermal management system of claim 1, wherein the sensor is further configured to measure at least one battery parameter, the BMS being further configured to determine, via the sensor, a battery parameter of the at least one battery and where performing thermal management of the at least one battery at least by causing the AC system and the fan to one or both of cool and heat battery is based on the determined temperature and the at least one battery parameter.

3. The thermal management system of claim 2, wherein the at least one battery parameter includes at least one of a battery resistance, a battery cell voltage, a state of charge of the battery, a battery current, a time parameter, and a frequency parameter.

4. The thermal management system of claim 2, wherein the sensor is further configured to measure a battery resistance, the BMS being further configured to determine, via the sensor, a battery resistance parameter of the at least one battery and where performing thermal management of the at least one battery at least by causing the AC system and the fan to one or both of cool and heat battery is based on the determined temperature and the determined battery resistance.

5. The thermal management system of claim 2, wherein the sensor is further configured to measure a battery cell voltage, the BMS being further configured to determine, via the sensor, a battery cell voltage parameter of the at least one battery and where performing thermal management of the at least one battery at least by causing the AC system and the fan to one or both of cool and heat battery is based on the determined temperature and the determined battery cell voltage of the at least one battery.

6. The thermal management system of claim 2, wherein the sensor is further configured to measure a state of charge of the at least one battery, the BMS being further configured to determine, via the sensor, a state of charge parameter of the at least one battery and where performing thermal management of the at least one battery at least by causing the AC system and the fan to one or both of cool and heat battery is based on the determined temperature and the determined state of charge of the at least one battery.

7. The thermal management system of claim 2, wherein the sensor is further configured to measure a battery current of the at least one battery, the BMS being further configured to determine, via the sensor, a battery current parameter of the at least one battery and where performing thermal management of the at least one battery at least by causing the AC system and the fan to one or both of cool and heat battery is based on the determined temperature and the determined battery current of the at least one battery.

8. The thermal management system of claim 1, where the battery 14 is at least one of a lead acid battery, a lithium ion battery, a nickel-metal hydride battery, and an ultracapacitor.

9. The thermal management system of claim 2, wherein the AC system receives signals from the BMS to activate the AC system or deactivate the AC system.

10. The thermal management system of claim 9, wherein the AC system is activated when the BMS determines that cooling or heating is needed based upon the determined temperature and the determined battery parameter.

11. The thermal management system of claim 1, wherein the fan receives signals from the BMS to increase the fan blower speed, decrease the fan blower speed, or deactivate the fan.

12. The thermal management system of claim 2, wherein the fan blower speed is increased when the BMS determines that cooling or heating is needed based upon the determined temperature and the determined battery parameter.

13. The thermal management system of claim 2, wherein the first AC line further comprises at least one valve in the first AC line, the first AC line being in fluid communication with the AC system and the battery, when the BMS determines that cooling or heating is needed based upon the determined temperature and the determined battery parameter, the BMS causes the at least one valve to change a valve position to an open position so that cooling or warming air can flow from the AC system to the battery.

14. The thermal management system of claim 13, wherein when the BMS determines that no cooling or heating is needed based upon the determined temperature and the determined battery parameter, the BMS causes the at least one valve to change the valve position from the open position to a closed position so that cooling or warming air cannot flow from the AC system to the battery.

15. The thermal management system of claim 1, the vehicle further including:
a second communication link in communication with the BMS, a device, and the vehicle;
a second AC line in fluid in communication with the AC system and the vehicle;
the first AC line being in communication with the battery and the second AC line being in communication with the vehicle and the AC system, the first AC line further including a valve that is movable from an open position to a closed position, moving the valve into the closed position in the first AC line will prevent solids, liquids, and gasses from flowing past the valve in the first AC line and moving the valve into the open position will allow solids, liquids, and gasses to flow past the valve in the first AC line; and
when the device determines that cooling or heating is needed based upon a determined temperature in the vehicle, the AC system is activated and cooling or heating air is sent into the second AC line into the vehicle.

16. A system for a vehicle having an air conditioning, AC, system with a first AC line, a second AC line, a first communication link, and a second communication link, the AC system being in fluid communication with the vehicle through a second air conditioning line and in electrical communication with the vehicle, the system comprising:
a thermal management system, the thermal management system comprising:
a battery that is in communication with the vehicle, in fluid communication with the AC system through the first AC line, and in electrical communication with the AC system through the first communication link;
a fan that is proximate the battery and in fluid communication with the battery;
a BMS comprising a first sensor configured to measure a first temperature of the battery and a second sensor configured to measure a second temperature of the vehicle, the BMS being in communication with the AC system and the fan; and
a device in communication with the BMS, the first sensor and the second sensor, the device being configured to:
determine, via the first sensor, a first temperature parameter of the battery based on the first temperature;
determine, via the second sensor, a second temperature parameter of the vehicle based on the second temperature; and
perform thermal management of the battery at least by causing the AC system and the fan to one or both of cool and heat battery based on one or both of the first temperature parameter and the second temperature parameter.

17. The system of claim 16, wherein the BMS can measure at least one battery parameter.

18. The system of claim 17, wherein the at least one battery parameter includes at least one of a battery resistance, a battery cell voltage, a battery current, a battery state of charge, a time parameter, a frequency parameter, and a temperature parameter.

19. A method for thermally managing a battery, the method being implemented by a thermal management system associated with at least one battery and having a fan that is proximate the battery and in fluid communication with the battery, a sensor configured to measure a temperature of the of the at least one battery, and a BMS in communication with the sensor and the fan, the thermal managing system being associated with a vehicle having an air conditioning, AC, system in fluid communication with the battery, the method comprising:
determining, via the sensor and the BMS, a temperature parameter of the at least one battery; and
performing, via the BMS, thermal management of the at least one battery at least by causing the AC system and the fan to one or both of cool and heat battery based on the determined temperature.

20. The method of claim 19, wherein the method further comprises continuously monitoring the temperature of the battery using the sensor.
